(19) United States
(12) Patent Application Publication
(10) Pub. No.: US 2024/0413611 A1
(43) Pub. Date: Dec. 12, 2024

(54) SURFACE EMITTING LASER AND METHOD FOR MANUFACTURING SURFACE EMITTING LASER

(71) Applicant: SONY SEMICONDUCTOR SOLUTIONS CORPORATION, KANAGAWA (JP)

(72) Inventor: YOSHITERU TACHIKAWA, KUMAMOTO (JP)

(21) Appl. No.: 18/699,911

(22) PCT Filed: Aug. 25, 2022
(86) PCT No.: PCT/JP2022/031991

§ 371 Date: Apr. 10, 2024

(30) Foreign Application Priority Data
Oct. 19, 2021 (JP) 2021-170715

(51) Int. Cl. H01S 5/183; H01S 5/042

(52) U.S. Cl. CPC H01S 5/18377; H01S 5/04256; H01S 5/18347; H01S 5/18369

(57) ABSTRACT

Provided is a surface emitting laser capable of reducing resistance while suppressing a decrease in reliability. The present technology provides a surface emitting laser including: a first structure including a first multilayer film reflector; a second structure including a second multilayer film reflector; and an active layer disposed between the first and second structures, in which the second structure includes a high-concentration impurity region having a relatively high impurity concentration in at least a part in a thickness direction including a first surface between the first surface, which is a surface on a side opposite to a side of the active layer, and a second surface which is a surface on the side of the active layer, and includes at least one impurity diffusion suppression layer between the first surface and the second surface. According to the present technology, it is possible to provide the surface emitting laser capable of reducing the resistance while suppressing the decrease in reliability.

### TECHNICAL FIELD

The technology according to the present disclosure (hereinafter also referred to as “the present technology”) relates to a surface emitting laser and a method for manufacturing a surface emitting laser.

### BACKGROUND ART

Conventionally, surface emitting lasers in which an active layer is disposed between first and second multilayer film reflectors are known.

Among the conventional surface emitting lasers, there is a surface emitting laser in which a region having a relatively high impurity concentration is provided on the second multilayer film reflector to reduce resistance (for example, see Patent Document 1).

### CITATION LIST

### Patent Document

Patent Document 1: Japanese Patent Application Laid-Open No. 2005-93634

### SUMMARY OF THE INVENTION

### Problems to be Solved by the Invention

However, in the conventional surface emitting lasers, it is not possible to reduce the resistance while suppressing a decrease in reliability.

Therefore, a main object of the present technology is to provide a surface emitting laser capable of reducing resistance while suppressing a decrease in reliability.

### Solutions to Problems

The present technology provides a surface emitting laser including:

a first structure including a first multilayer film reflector;

a second structure including a second multilayer film reflector; and

an active layer disposed between the first and second structures,

in which the second structure includes a high-concentration impurity region having a relatively high impurity concentration in at least a part in a thickness direction including a first surface between the first surface, which is a surface on a side opposite to a side of the active layer, and a second surface which is a surface on the side of the active layer, and includes at least one impurity diffusion suppression layer between the first surface and the second surface.

The second multilayer film reflector may have a pair of a high Al composition layer having a relatively high Al composition, and a low Al composition layer having a relatively low Al composition, and

an optical thickness of the high Al composition layer may be thicker than an optical thickness of the low Al composition layer.

The impurity diffusion suppression layer may be disposed between at least a part of the high-concentration impurity region and the active layer.

The impurity diffusion suppression layer may contain In.

The impurity diffusion suppression layer may be made of a GaInP-based compound semiconductor or a GaInAs-based compound semiconductor.

The impurity diffusion suppression layer may contain Al.

The impurity diffusion suppression layer may have an Al composition of 1% or more and 15% or less.

Shen an oscillation wavelength of the surface emitting laser is λ, an optical thickness of the impurity diffusion suppression layer may be λ/4 or more and λ or less.

The high-concentration impurity region may have an annular shape in plan view, and a difference between an outer diameter and an inner diameter of the high-concentration impurity region may be 1 μm or more.

The at least one impurity diffusion suppression layer may be a plurality of impurity diffusion suppression layers.

The second structure may include an oxidation confinement layer between the first surface and the second surface.

The impurity diffusion suppression layer may be disposed between the first surface and the oxidation confinement layer.

The impurity diffusion suppression layer may be disposed between at least a part of the high-concentration impurity region and the oxidation confinement layer.

The impurity diffusion suppression layer may be disposed between the oxidation confinement layer and the active layer.

The at least one impurity diffusion suppression layer may be a plurality of impurity diffusion suppression layers, and at least one of the plurality of impurity diffusion suppression layers may be disposed between the first surface and the oxidation confinement layer.

The at least one impurity diffusion suppression layer may be a plurality of impurity diffusion suppression layers, and at least one of the plurality of impurity diffusion suppression layers may be disposed between at least a part of the high-concentration impurity region and the oxidation confinement layer.

The at least one impurity diffusion suppression layer may be a plurality of impurity diffusion suppression layers, and at least one of the plurality of impurity diffusion suppression layers may be disposed between the oxidation confinement layer and the active layer.

The high-concentration impurity region may contain any of Zn, B, and Be.

The at least one impurity diffusion suppression layer may be a plurality of impurity diffusion suppression layers, a part of the plurality of impurity diffusion suppression layers may be disposed between the first surface and the oxidation confinement layer, and another part of the plurality of impurity diffusion suppression layers may be disposed between the oxidation confinement layer and the active layer.

The at least one impurity diffusion suppression layer may be a plurality of impurity diffusion suppression layers, a part of the plurality of impurity diffusion suppression layers may be disposed between at least a part of the high-concentration impurity region and the oxidation confinement layer, and another part of the plurality of impurity diffusion suppression layers may be disposed between the oxidation confinement layer and the active layer.

The present technology also provides a method for manufacturing a surface emitting laser, the method including: a process of laminating a first structure including a first multilayer film reflector, an active layer, and a second structure including an impurity diffusion suppression layer and a second multilayer film reflector in this order; and a process of diffusing impurities from a surface of the second structure on a side opposite to a side of the active layer.

### BRIEF DESCRIPTION OF DRAWINGS

FIG. 1 is a cross-sectional view illustrating a configuration of a surface emitting laser according to a first embodiment of the present technology.

FIG. 2 is a flowchart for describing a first example of a method for manufacturing the surface emitting laser according to the first embodiment of the present technology.

FIGS. 3A and 3B are cross-sectional views for each process of the first example of the method for manufacturing a surface emitting laser according to the first embodiment of the present technology.

FIGS. 4A to 4C are cross-sectional views for each process of the first example of the method for manufacturing the surface emitting laser according to the first embodiment of the present technology.

FIGS. 5A and 5B are cross-sectional views for each process of the first example of the method for manufacturing the surface emitting laser according to the first embodiment of the present technology.

FIGS. 6A and 6B are cross-sectional views for each process of the first example of the method for manufacturing the surface emitting laser according to the first embodiment of the present technology.

FIGS. 7A and 7B are cross-sectional views for each process of the first example of the method for manufacturing the surface emitting laser according to the first embodiment of the present technology.

FIGS. 8A and 8B are cross-sectional views for each process of the first example of the method for manufacturing the surface emitting laser according to the first embodiment of the present technology.

FIGS. 9A and 9B are cross-sectional views for each process of the first example of the method for manufacturing the surface emitting laser according to the first embodiment of the present technology.

FIG. 10 is a cross-sectional view for each process of the first example of the method for manufacturing the surface emitting laser according to the first embodiment of the present technology.

FIG. 11 is a flowchart for describing a second example of the method for manufacturing the surface emitting laser according to the first embodiment of the present technology.

FIGS. 12A and 12B are cross-sectional views for each process of the second example of the method for manufacturing the surface emitting laser according to the first embodiment of the present technology.

FIGS. 13A and 13B are cross-sectional views for each process of the second example of the method for manufacturing the surface emitting laser according to the first embodiment of the present technology.

FIGS. 14A to 14C are cross-sectional views for each process of the second example of the method for manufacturing the surface emitting laser according to the first embodiment of the present technology.

FIGS. 15A and 15B are cross-sectional views for each process of the second example of the method for manufacturing the surface emitting laser according to the first embodiment of the present technology.

FIG. 16 is a cross-sectional view illustrating a configuration of a surface emitting laser according to a modification example of the first embodiment of the present technology.

FIG. 17 is a cross-sectional view illustrating a configuration of a surface emitting laser according to a second embodiment of the present technology.

FIG. 18 is a flowchart for describing a method for manufacturing the surface emitting laser according to the second embodiment of the present technology.

FIGS. 19A and 19B are cross-sectional views for each process of the method for manufacturing the surface emitting laser according to the second embodiment of the present technology.

FIGS. 20A and 20B are cross-sectional views for each process of the method for manufacturing the surface emitting laser according to the second embodiment of the present technology.

FIGS. 21A and 21B are cross-sectional views for each process of the method for manufacturing the surface emitting laser according to the second embodiment of the present technology.

FIGS. 22A to 22C are cross-sectional views for each process of the method for manufacturing the surface emitting laser according to the second embodiment of the present technology.

FIGS. 23A and 23B are cross-sectional views for each process of the method for manufacturing the surface emitting laser according to the second embodiment of the present technology.

FIGS. 24A and 24B are cross-sectional views for each process of the method for manufacturing the surface emitting laser according to the second embodiment of the present technology.

FIGS. 25A and 25B are cross-sectional views for each process of the method for manufacturing the surface emitting laser according to the second embodiment of the present technology.

FIG. 26 is a cross-sectional view for each process of the method for manufacturing the surface emitting laser according to the second embodiment of the present technology.

FIG. 27 is a cross-sectional view illustrating a configuration of a surface emitting laser according to Modification Example 1 of the second embodiment of the present technology.

FIG. 28 is a cross-sectional view illustrating a configuration of a surface emitting laser according to Modification Example 2 of the second embodiment of the present technology.

FIG. 29 is a cross-sectional view illustrating a configuration of a surface emitting laser according to a third embodiment of the present technology.

FIG. 30 is a cross-sectional view illustrating a configuration of a surface emitting laser according to a modification example of the third embodiment of the present technology.

FIG. 31 is a cross-sectional view illustrating a configuration of a surface emitting laser according to a fourth embodiment of the present technology.

FIG. 32 is a cross-sectional view illustrating a configuration of a surface emitting laser according to Modification Example 1 of the fourth embodiment of the present technology.

FIG. 33 is a cross-sectional view illustrating a configuration of a surface emitting laser according to Modification Example 2 of the fourth embodiment of the present technology.

FIG. 34 is a diagram illustrating an application example of the surface emitting laser according to the first embodiment of the present technology to a distance measuring device.

FIG. 35 is a block diagram illustrating an example of a schematic configuration of a vehicle control system.

FIG. 36 is an explanatory view illustrating an example of an installation position of the distance measuring device.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments described below illustrate representative embodiments of the present technology, and the scope of the present technology is not narrowly interpreted by these embodiments. In this specification, even in a case where it is described that each of a surface emitting laser and a method for manufacturing a surface emitting laser according to the present technology exhibit a plurality of effects, it is only required that each of the surface emitting laser and the method for manufacturing a surface emitting laser according to the present technology exhibit at least one effect. The effects described in the present specification are merely examples and are not limited, and other effects may be provided.

Furthermore, the description will be given in the following order.
1. Introduction
2. Surface Emitting Laser According to First Embodiment of Present Technology
3. Surface Emitting Laser According to Modification Example of First Embodiment of Present Technology
4. Surface Emitting Laser According to Second Embodiment of Present Technology
5. Surface Emitting Laser According to Modification Example 1 of Second Embodiment of Present Technology
6. Surface Emitting Laser According to Modification Example 2 of Second Embodiment of Present Technology
7. Surface Emitting Laser According to Third Embodiment of Present Technology
8. Surface Emitting Laser According to Modification Example of Third Embodiment of Present Technology
9. Surface Emitting Laser According to Fourth Embodiment of Present Technology
10. Surface Emitting Laser According to Modification Example 1 of Fourth Embodiment of Present Technology
11. Surface Emitting Laser According to Modification Example 2 of Fourth Embodiment of Present Technology
12. Other Modification Examples of Present Technology
13. Application Example to Electronic Device
14. Example in which Surface Emitting Laser Is Applied to Distance Measuring Device
15. Example in which Distance Measuring Device Is Mounted on Mobile Body

### 1. INTRODUCTION

In a vertical cavity surface emitting laser (VCSEL), resistance increases when the number of layers is simply increased in order to achieve high reflectance of a DBR (multilayer film reflector). For this reason, it is general to reduce the number of layers and suppress the increase in resistance by expanding a difference in refractive index between adjacent layers by forming the DBR with a pair of a high refractive index layer and a low refractive index layer.

Furthermore, it is known that impurity diffusion is performed on a part of the DBR to reduce the resistance in order to obtain low-resistance electrical characteristics in the DBR. For example, in an AlGaAs-based VCSEL, a DBR is generally configured using an AlGaAs layer having a high Al composition (for example, an Al composition of about 0.9) as a low refractive index layer and using an AlGaAs layer or a GaAs layer having a low Al composition as a high refractive index layer.

However, in a case where the impurity diffusion is performed on the DBR, excessive diffusion occurs regarding a target diffusion depth of the impurity diffusion. Conventionally, it has been assumed that the impurity diffusion stops due to pile-up of concentration at an interface between adjacent layers of the DBR. In practice, however, it has been confirmed that many layers that are not intended are also affected by the impurity diffusion.

This is considered to be because the respective refractive index layers of the DBR are thin films. These impurities cause problems such as a decrease in controllability of an oxide layer due to a decrease in an oxidation rate during formation of an oxidation confinement layer and/or a decrease in reliability due to entry of impurities into an active layer.

Therefore, in order to avoid such problems, the inventor has developed a surface emitting laser and a method for manufacturing a surface emitting laser according to the present technology.

### 2. SURFACE EMITTING LASER ACCORDING TO FIRST EMBODIMENT OF PRESENT TECHNOLOGY

### <<Configuration of Surface Emitting Laser>>

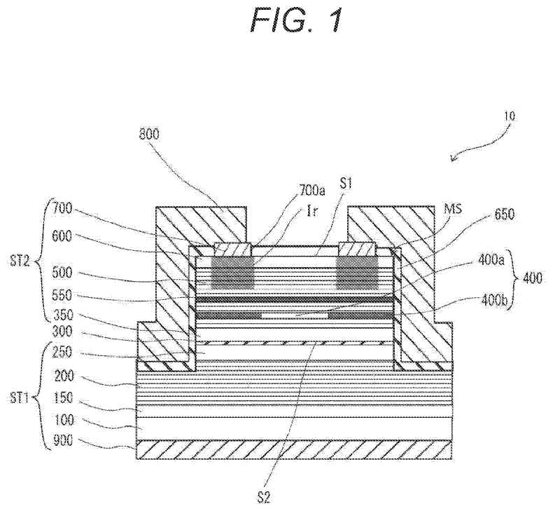

FIG. 1 is a cross-sectional view illustrating a configuration of a surface emitting laser 10 according to a first embodiment of the present technology. Hereinafter, for the sake of convenience, the upper part in the cross-sectional view of FIG. 1 and the like will be described as an upper side, and the lower part in the cross-sectional view of FIG. 1 and the like will be described as a lower side.

Hereinafter, a case where a surface emitting laser array in which a plurality of the surface emitting lasers 10 is two-dimensionally arranged is configured will be described as an example. One surface emitting laser 10 of the surface emitting laser array is extracted and illustrated in FIG. 1.

### (Overall Configuration)

As illustrated in FIG. 1, the surface emitting laser 10 includes a first structure ST1 including a first multilayer film reflector 200, a second structure ST2 including a second multilayer film reflector 500, and an active layer 300 disposed between the first and second structures ST1 and ST2.

More specifically, the surface emitting laser 10 has a laminated structure in which the first multilayer film reflector 200, the active layer 300, and the second multilayer film reflector 500 are laminated in this order on a substrate 100.

As an example, the first structure ST1 includes the substrate 100, a cathode electrode 900, and a first cladding layer 250 in addition to the first multilayer film reflector 200.

As an example, the second structure ST2 includes a second cladding layer 350, an oxidation confinement layer 400, a contact layer 600, and an anode electrode 700 in addition to the second multilayer film reflector 500.

The second structure ST2 further includes, as an example, a high-concentration impurity region Ir and an impurity diffusion suppression layer 550.

### (Substrate)

The substrate 100 is, for example, a GaAs substrate of a first conductivity type (for example, n-type).

A buffer layer 150 is disposed between a surface (upper surface) of the substrate 100 on the first multilayer film reflector 200 side and the first multilayer film reflector 200.

The cathode electrode 900 of the first conductivity type (for example, n-type) is provided on a surface (lower surface) of the substrate 100 on a side opposite to the first multilayer film reflector 200 side.

### (Cathode Electrode)

The cathode electrode 900 may have a single-layer structure or a laminated structure. The cathode electrode 900 is constituted by, for example, at least one type of metal (including an alloy) selected from a group including Au, Ag, Pd, Pt, Ni, Ti, V, W, Cr, Al, Cu, Zn, Sn, and In. In the case of being a laminated structure, the cathode electrode 900 is constituted by a material such as, for example, Ti/Au, Ti/Al, Ti/Al/Au, Ti/Pt/Au, Ni/Au, Ni/Au/Pt, Ni/Pt, Pd/Pt, or Ag/Pd.

As an example, the cathode electrode 900 is electrically connected to a cathode (negative electrode) of the laser driver.

### (First Multilayer Film Reflector)

The first multilayer film reflector 200 is, for example, a semiconductor multilayer film reflector. The multilayer film reflector is also referred to as a distributed Bragg reflector. A semiconductor multilayer film reflector which is a type of multilayer film reflector (distributed Bragg reflector) has low light absorption and high reflectance. The first multilayer film reflector 200 is also referred to as a lower DBR.

As an example, the first multilayer film reflector 200 is a semiconductor multilayer film reflector of a first conductivity type (for example, n-type), and has a structure in which a plurality of types (for example, two types) of semiconductor layers (refractive index layers) having different refractive indexes is alternately laminated with an optical thickness of ¼ (λ/4) of the oscillation wavelength λ. Each refractive index layer of the first multilayer film reflector 200 is constituted by an AlGaAs-based compound semiconductor of the first conductivity type (for example, n-type).

### (First Cladding Layer)

The first cladding layer 250 is disposed between the first multilayer film reflector 200 and the active layer 300. The first cladding layer 250 is constituted by a first conductivity type (for example, n-type) AlGaAs-based compound semiconductor. The “cladding layer” is also referred to as a “spacer layer”.

### (Active Layer)

The active layer 300 has a quantum well structure including a barrier layer including, for example, an AlGaAs-based compound semiconductor, and a quantum well layer. This quantum well structure may be a single quantum well structure (QW structure) or a multiple quantum well structure (MQW structure).

### (Second Cladding Layer)

The second cladding layer 350 is disposed between the second multilayer film reflector 500 and the active layer 300. The second cladding layer 350 is constituted by a second conductivity type (for example, p-type) AlGaAs-based compound semiconductor. The “cladding layer” is also referred to as a “spacer layer”.

The second multilayer film reflector 500 is, as an example, a semiconductor multilayer film reflector of a second conductivity type (for example, p-type), and may have a structure in which a plurality of types (for example, two types) of semiconductor layers (refractive index layers) having mutually different refractive indexes are alternately layered with an optical thickness of ¼ wavelength (λ/4) of an oscillation wavelength λ. As an example, each refractive index layer of the second multilayer film reflector 500 is formed by an AlGaAs-based compound semiconductor of the second conductivity type (for example, p-type).

The second multilayer film reflector 500 may have a pair of a high Al composition layer (low refractive index layer) having a relatively high Al composition and a low Al composition layer (high refractive index layer) having a relatively low Al composition, and an optical thickness (optical film thickness) of the high Al composition layer may be thicker than the optical thickness (optical film thickness) of the low Al composition layer. In this case, the film thickness of the low Al composition layer is preferably, for example, 41 nm or less.

Since the second multilayer film reflector 500 has such a modulation film thickness in which the optical film thickness of the high Al composition layer is larger than the optical film thickness of the low Al composition layer, it is possible to set a more suitable condition for promoting impurity diffusion in the reflector. As a specific example of the modulation film thickness, for example, the optical thickness of the high Al composition layer can be set to λ/4×1.3, and the optical thickness of the low Al composition can be set to λ/4×0.7.

### (Oxidation Confinement Layer)

As an example, the oxidation confinement layer 400 is disposed inside the second multilayer film reflector 500.

As an example, the oxidation confinement layer 400 includes a non-oxidized region 400a formed by AlAs and an oxidized region 400b formed by an oxide of AlAs (for example, Al₂O₃) surrounding the non-oxidized region. The oxidation confinement layer 400 has a current/light confinement function.

### (Contact Layer)

The contact layer 600 is disposed on the second multilayer film reflector 500. The contact layer 600 is constituted by, for example, a GaAs-based compound semiconductor of the second conductivity type (for example, p-type).

Here, as an example, a mesa structure MS is formed on a part (lower portion) of the first multilayer film reflector 200. More specifically, the mesa structure MS includes, as an example, the other part (upper portion) of the first multilayer film reflector 200, the first cladding layer 250, the active layer 300, the second cladding layer 350, the oxidation confinement layer 400, the second multilayer film reflector 500, and the contact layer 600.

The cathode electrode 900, the substrate 100, the buffer layer 150, and the part (lower portion) of the first multilayer film reflector are shared by the plurality of surface emitting lasers 10.

The mesa structure MS has, for example, a substantially cylindrical shape in plan view, but may have another columnar shape such as a substantially elliptical columnar shape or a polygonal columnar shape.

### (Anode Electrode)

For example, the anode electrode 700 is disposed so as to surround (for example, annularly) the non-oxidized region 400a of the oxidation confinement layer 400 and to be in contact with the contact layer 600 when viewed from a height direction of the mesa structure MS. An inner diameter side of the anode electrode 700 is an emission port 700a.

The anode electrode 700 may have a single layer structure or a laminated structure. The anode electrode 700 contains, for example, at least one type of metal (including an alloy) selected from a group including Au, Ag, Pd, Pt, Ni, Ti, V, W, Cr, Al, Cu, Zn, Sn, and In. In the case of being a laminated structure, the anode electrode 700 is constituted by a material such as, for example, Ti/Au, Ti/Al, Ti/Al/Au, Ti/Pt/Au, Ni/Au, Ni/Au/Pt, Ni/Pt, Pd/Pt, or Ag/Pd.

The mesa structure MS and a peripheral portion thereof are covered with an insulating film 650 except for a region where the anode electrode 700 is formed (including the emission port 700a). The insulating film 650 is constituted by a dielectric such as SiO₂, SiN, or SiON.

On the insulating film 650, a wiring layer 800 whose end is connected to the anode electrode 700 is formed. The wiring layer 800 is made of, for example, gold plating. In the wiring layer 800, an opening is formed at a position corresponding to the emission port 700a.

As an example, the anode electrode 700 is connected to an anode (positive electrode) of a laser driver via the wiring layer 800.

### (High-Concentration Impurity Region)

The high-concentration impurity region Ir means a region (region having low electric resistance) having a relatively high impurity concentration (as compared to the other regions). The high-concentration impurity region Ir preferably contains, for example, any of Zn, B, and Be.

The high-concentration impurity region Ir is provided in at least a part (for example, a part) in the thickness direction including a first surface S1 between the first surface S1 (for example, an upper surface of the contact layer 600), which is a surface on a side opposite to the active layer 300 side of the second structure ST2, and a second surface S2 (for example, a lower surface of the second cladding layer 350) which is a surface on the active layer 300 side.

More specifically, as an example, the high-concentration impurity region Ir is provided in the entire region in the thickness direction of the contact layer 600 and a part (upper portion) in the thickness direction of the second multilayer film reflector 500. That is, the high-concentration impurity region Ir is provided to straddle the contact layer 600 and the second multilayer film reflector 500.

As an example, the high-concentration impurity region Ir is provided in an annular shape in plan view so as to correspond to the anode electrode 700. A difference between an outer diameter and an inner diameter of the high-concentration impurity region Ir is preferably 1 μm or more.

As can be seen from the above description, the high-concentration impurity region Ir is provided on a current path between the anode electrode 700 and the active layer 300. A portion of the high-concentration impurity region Ir provided in the second multilayer film reflector 500 has electrically lower resistance (excellent conductivity) than a region of the second multilayer film reflector 500 where the high-concentration impurity region Ir is not provided. A portion of the high-concentration impurity region Ir provided in the contact layer 600 has electrically lower resistance (excellent conductivity) than a region of the contact layer 600 where the high-concentration impurity region Ir is not provided. Therefore, low-voltage driving is possible.

### (Impurity Diffusion Suppression Layer)

The impurity diffusion suppression layer 550 is disposed between the first surface S1 and the second surface S2. More specifically, as an example, the impurity diffusion suppression layer 550 is disposed between at least a part (for example, whole) of the high-concentration impurity region Ir and the active layer 300. Here, the impurity diffusion suppression layer 550 is located below (on the second surface S2 side of) a lower end (diffusion depth) of the high-concentration impurity region Ir.

Here, the second structure ST2 has the oxidation confinement layer 400 between the first surface S1 and the second surface S2 as described above.

As an example, the impurity diffusion suppression layer 550 is disposed between the first surface S1 and the oxidation confinement layer 400. More specifically, as an example, the impurity diffusion suppression layer 550 is disposed between at least a part (for example, whole) of the high-concentration impurity region Ir and the oxidation confinement layer 400 in the second multilayer film reflector 500.

The impurity diffusion suppression layer 550 may contain In as an example. Specifically, the impurity diffusion suppression layer 550 may be made of, for example, a GaInP-based compound semiconductor, a GaInAs-based compound semiconductor, or the like. In this case, the impurity diffusion suppression layer 550 preferably has an In composition of 5% or more.

The impurity diffusion suppression layer 550 may contain Al, for example. In this case, the impurity diffusion suppression layer 550 preferably has an Al composition of 1% or more and 15% or less. The impurity diffusion suppression layer 550 may be made of, for example, an AlGaAs-based compound semiconductor, an AlGaInP-based compound semiconductor, or the like.

When an oscillation wavelength of the surface emitting laser 10 is λ, an optical thickness of the impurity diffusion suppression layer 550 is preferably λ/4 or more and λ or less.

### <<Operation of Surface Emitting Laser>>

In the surface emitting laser 10, a current flows into the anode electrode 700 from the anode side of the laser driver via the wiring layer 800. The current flowing into the anode electrode 700 is narrowed by the oxidation confinement layer 400 via the high-concentration impurity region Ir and the impurity diffusion suppression layer 550, and is injected into the active layer 300 via the second cladding layer 350. Therefore, the active layer 300 emits light, and the light repeatedly reciprocates while being narrowed by the oxidation confinement layer 400 and amplified by the active layer 300 between the first and second multilayer film reflectors 200 and 500, and is emitted as laser light from the emission port 700a when an oscillation condition is satisfied. The current injected into the active layer 300 flows out to the cathode side of the laser driver via the first cladding layer 250, the first multilayer film reflector 200, the buffer layer 150, the substrate 100, and the cathode electrode 900.

### <<First Example of Method for Manufacturing Surface Emitting Laser>>

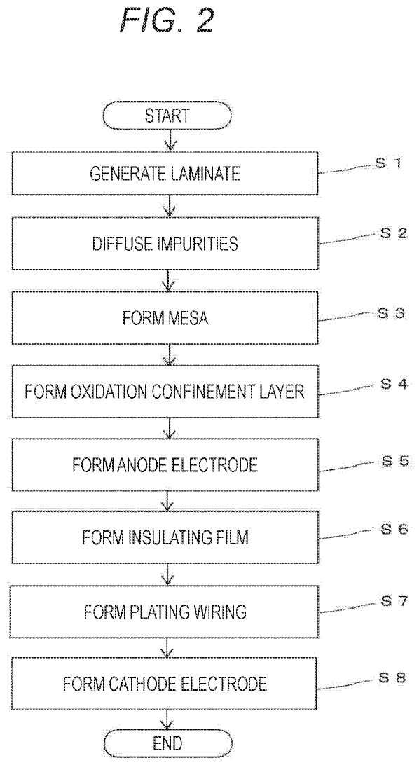

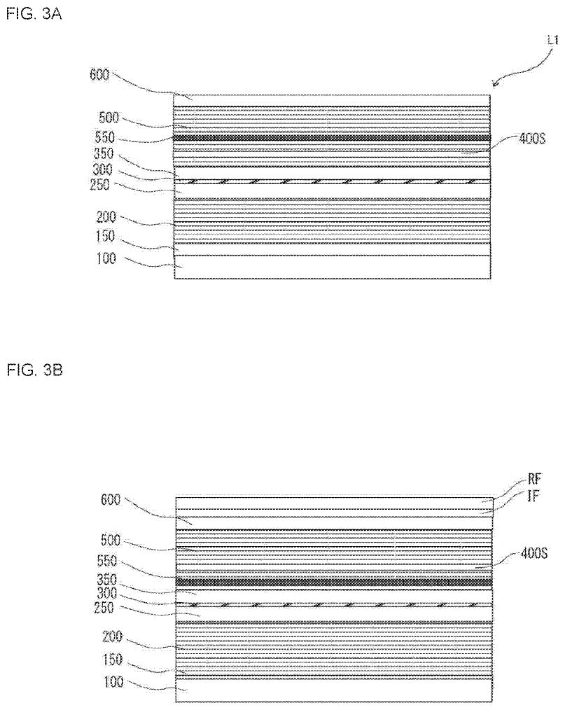

Hereinafter, a first example of a method for manufacturing the surface emitting laser 10 according to the first embodiment will be described with reference to FIGS. 2 to 10. FIG. 2 is a flowchart for describing the first example of the method for manufacturing the surface emitting laser 10. FIGS. 3A to 10 are cross-sectional views (process cross-sectional views) for each process of the first example of the method for manufacturing the surface emitting laser 10. Here, as an example, a plurality of surface emitting laser arrays is simultaneously generated on one wafer, which is a base material of the substrate 100, by a semiconductor manufacturing method (at this time, the plurality of surface emitting lasers 10 of each of the surface emitting laser arrays is also simultaneously generated). Next, the plurality of surface emitting laser arrays integrated in series is separated from each other to obtain a plurality of chip-shaped surface emitting laser arrays (surface emitting laser array chips).

In the first step S1, a laminate is generated. Specifically, using a chemical vapor deposition (CVD) method, for example, a metal organic chemical vapor deposition (MOCVD) method, the buffer layer 150, the first multilayer film reflector 200, the first cladding layer 250, the active layer 300, the second cladding layer 350, the second multilayer film reflector 500 including a selected oxide layer 400S and the impurity diffusion suppression layer 550 in this order from the substrate 100 side, and the contact layer 600 are laminated in this order on the substrate 100 to generate a laminate L1 (see FIG. 3A).

In the next step S2, impurities are diffused.

Specifically, first, an insulating film IF made of, for example, SiN and a resist film RF are laminated in this order on an upper surface of the laminate L1 (for example, an upper surface of the contact layer 600) (see FIG. 3B).

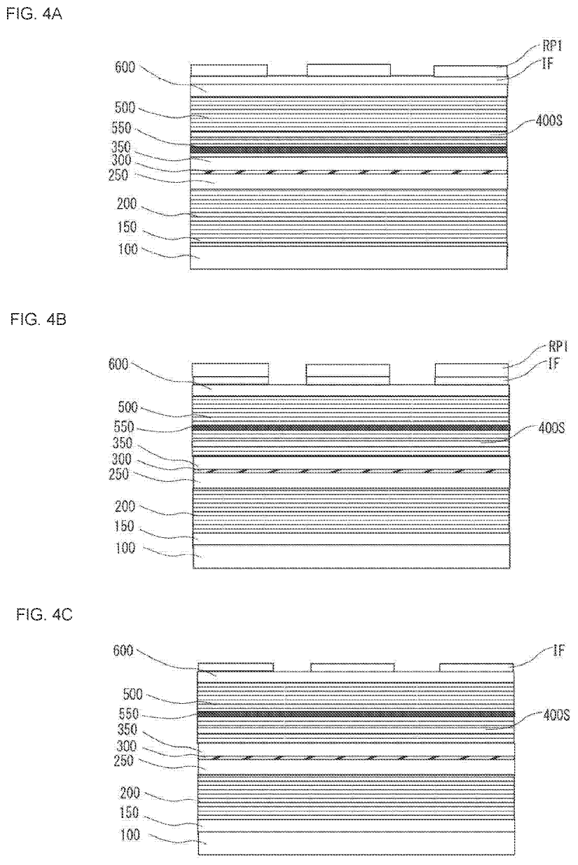

Next, the resist film RF is exposed to form an annular resist pattern RP1 in which a region corresponding to a region where the high-concentration impurity region Ir is to be formed is opened (see FIG. 4A). An opening width (a difference between inner and outer diameters) of the resist pattern RP1 at this time is preferably 1 μm or more.

Next, the insulating film IF is etched using the resist pattern RP1 as a mask (see FIG. 4B).

Next, the resist pattern RP1 is removed by etching (see FIG. 4C).

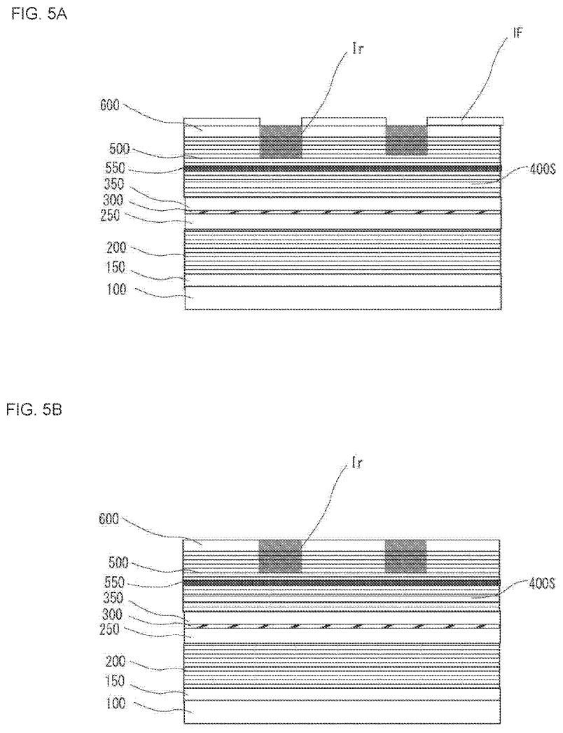

Next, using the insulating film IF as a mask, impurities such as Zn are implanted and diffused through the contact layer 600 by a method such as gas phase or solid phase diffusion (see FIG. 5A). Here, as an example, an impurity diffusion depth is adjusted such that the high-concentration impurity region Ir is located slightly above the impurity diffusion suppression layer 550.

Finally, the insulating film IF is removed by etching (see FIG. 5B).

In the next step S3, a mesa is generated.

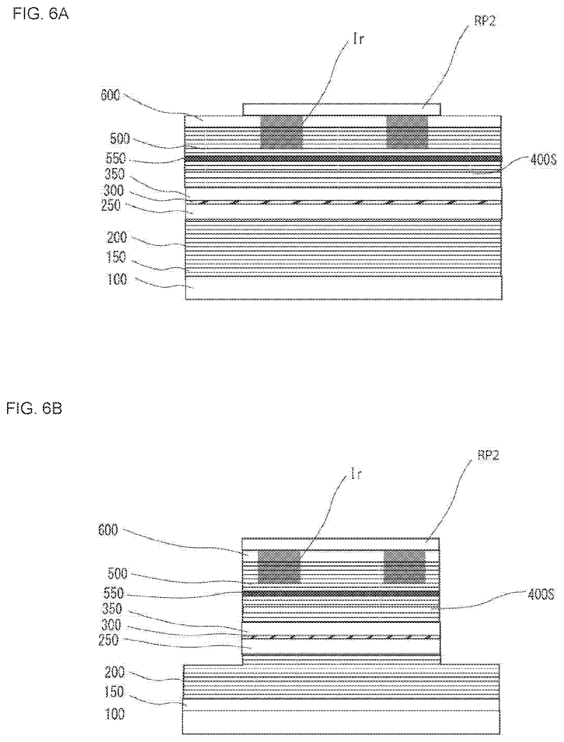

Specifically, first, a resist pattern RP2 for forming the mesa to be the mesa structure MS is formed on the laminate in which the high-concentration impurity region Ir is formed (see FIG. 6A).

Next, the laminate is etched using the resist pattern RP2 as a mask to form the mesa (see FIG. 6B). The etching here is performed such that an etching bottom surface is located in the first multilayer film reflector 200.

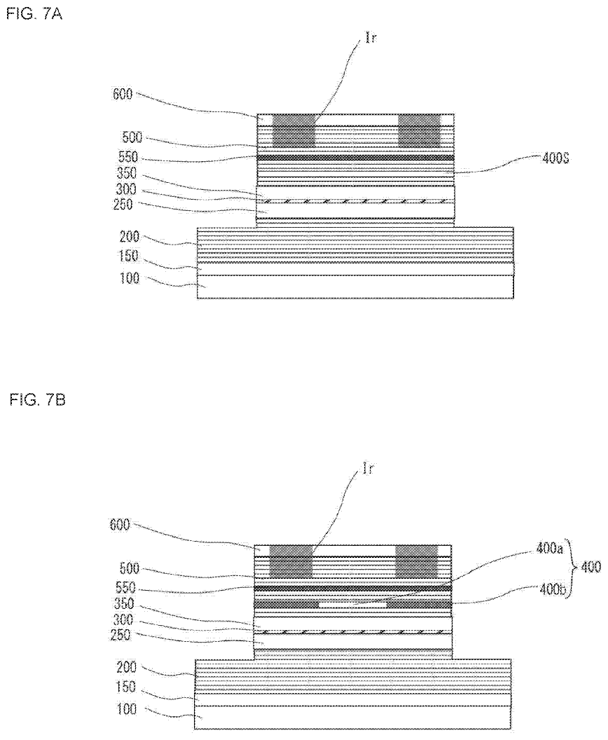

Finally, the resist pattern RP2 is removed by etching (see FIG. 7A).

In the next step S4, the oxidation confinement layer 400 is formed (see FIG. 7B). Specifically, the mesa is exposed to a water vapor atmosphere, and the selected oxide layer 400S is oxidized (selectively oxidized) from a side surface to form the oxidation confinement layer 400 in which the non-oxidized region 400a is surrounded by the oxidized region 400b.

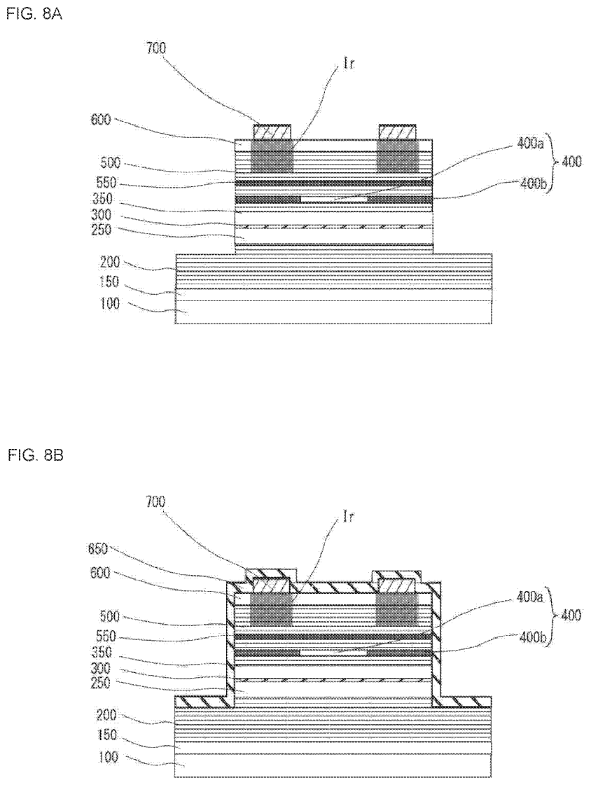

In the next step S5, the anode electrode 700 is formed (see FIG. 8A). Specifically, an electrode material of the anode electrode 700 is formed on the high-concentration impurity region Ir by, for example, sputtering, a vapor deposition method, or the like, and a resist and the electrode material on the resist are lifted off to form the anode electrode 700 on the high-concentration impurity region Ir.

In the next step S6, the insulating film 650 is formed.

Specifically, first, the insulating film 650 made of SiN, for example, is formed on the entire surface (see FIG. 8B).

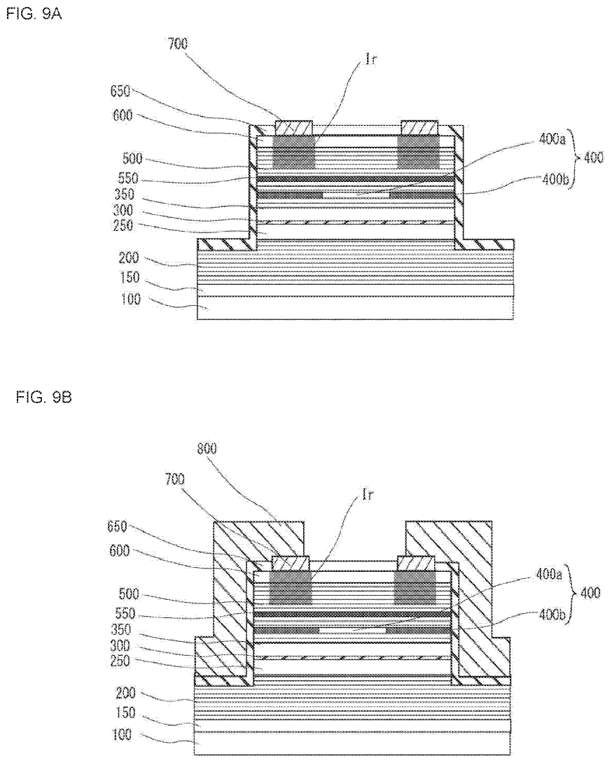

Next, the insulating film 650 on the anode electrode 700 and on the inner diameter side of the anode electrode 700 is removed by etching (see FIG. 9A). As a result, the anode electrode 700 is exposed, and the emission port 700a is opened.

In the next step S7, the wiring layer 800 is formed (see FIG. 9B). Specifically, the wiring layer 800 is formed on the insulating film 650 such that a part thereof is in contact with the anode electrode 700.

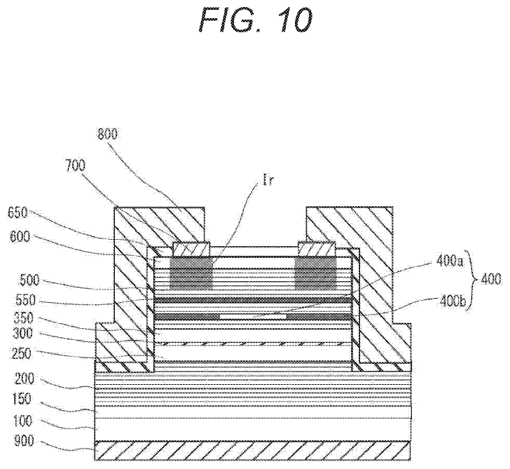

In the next step S8, the cathode electrode 900 is formed (see FIG. 10).

Specifically, first, the entire thickness is set to about 100 μm by polishing a back surface of the substrate 100 (back surface of the wafer).

Next, an electrode material of the cathode electrode 900 is formed into a solid film on the back surface of the substrate 100.

Thereafter, processing such as annealing is performed, thereby the plurality of surface emitting laser arrays in which the plurality of surface emitting lasers 10 is two-dimensionally arranged is formed on one wafer. Thereafter, dicing is performed to separate the plurality of surface emitting laser array chips.

### <<Second Example of Method for Manufacturing Surface Emitting Laser>>

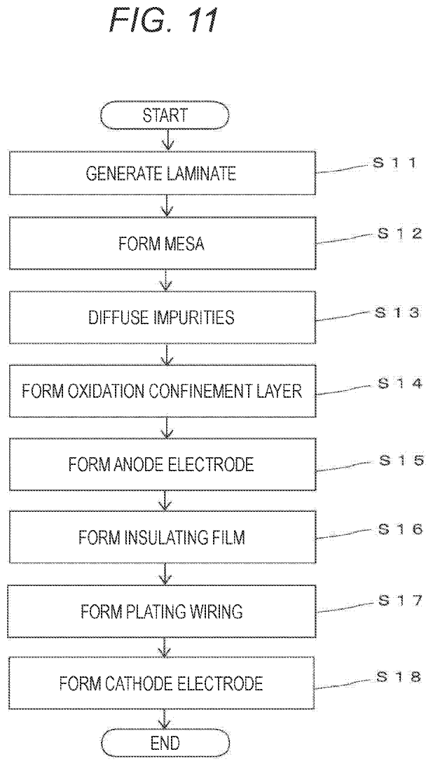

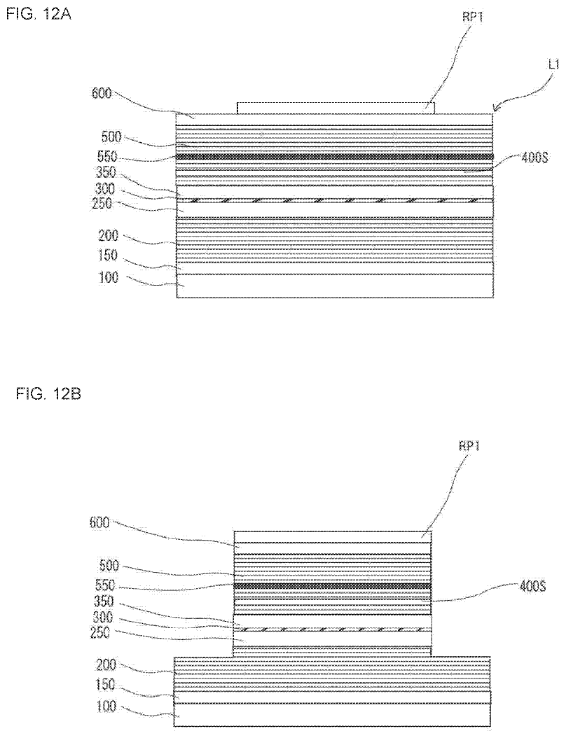

Hereinafter, a second example of a method for manufacturing the surface emitting laser 10 according to the first embodiment will be described with reference to FIGS. 3A, 7B to 10, and 11 to 15B. FIG. 11 is a flowchart for describing the second example of the method for manufacturing the surface emitting laser 10. FIGS. 12A to 15B are cross-sectional views (process cross-sectional views) for each process of the second example of the method for manufacturing the surface emitting laser 10. Here, as an example, a plurality of surface emitting laser arrays is simultaneously generated on one wafer, which is a base material of the substrate 100, by a semiconductor manufacturing method (at this time, the plurality of surface emitting lasers 10 of each of the surface emitting laser arrays is also simultaneously generated). Next, the plurality of surface emitting laser arrays integrated in series is separated from each other to obtain a plurality of chip-shaped surface emitting laser arrays (surface emitting laser array chips).

In the first step S11, a laminate is generated. Specifically, using a chemical vapor deposition (CVD) method, for example, a metal organic chemical vapor deposition (MOCVD) method, the buffer layer 150, the first multilayer film reflector 200, the first cladding layer 250, the active layer 300, the second cladding layer 350, the second multilayer film reflector 500 including a selected oxide layer 400S and the impurity diffusion suppression layer 550 in this order from the substrate 100 side, and the contact layer 600 are laminated in this order on the substrate 100 to generate a laminate L1 (see FIG. 3A).

In the next step S12, a mesa is generated.

Specifically, first, the resist pattern RP1 for forming a mesa to be the mesa structure MS is formed on the laminate L1 (see FIG. 12A).

Next, the laminate L1 is etched using the resist pattern RP1 as a mask to form the mesa (see FIG. 12B). The etching here is performed such that an etching bottom surface is located in the first multilayer film reflector 200.

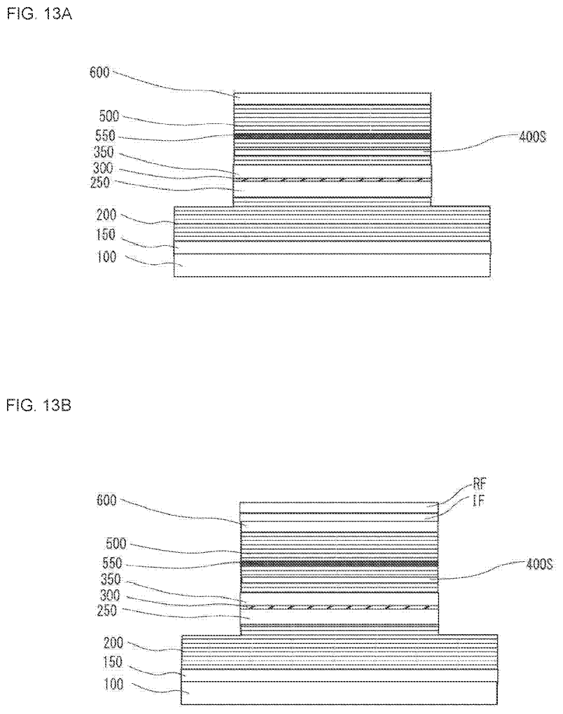

Finally, the resist pattern RP1 is removed by etching (see FIG. 13A).

In the next step S13, impurities are diffused.

Specifically, first, the insulating film IF made of, for example, SiN and a resist film RF are laminated in this order on an upper surface of the mesa (for example, an upper surface of the contact layer 600) (see FIG. 13B).

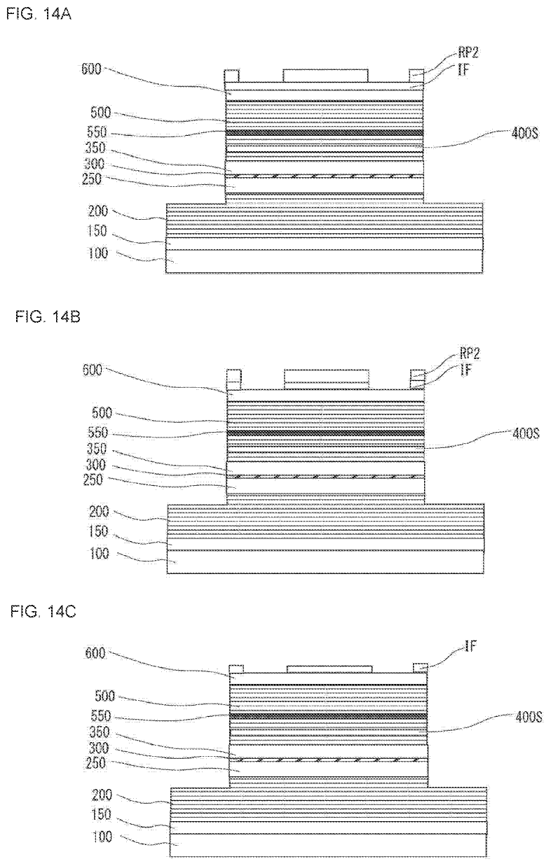

Next, the resist film RF is exposed to form the annular resist pattern RP2 in which a region corresponding to a region where the high-concentration impurity region Ir is to be formed is opened (see FIG. 14A). An opening width (a difference between inner and outer diameters) of the resist pattern RP2 at this time is preferably 1 μm or more.

Next, the insulating film IF is etched using the resist pattern RP2 as a mask (see FIG. 14B).

Next, the resist pattern RP2 is removed by etching (see FIG. 14C).

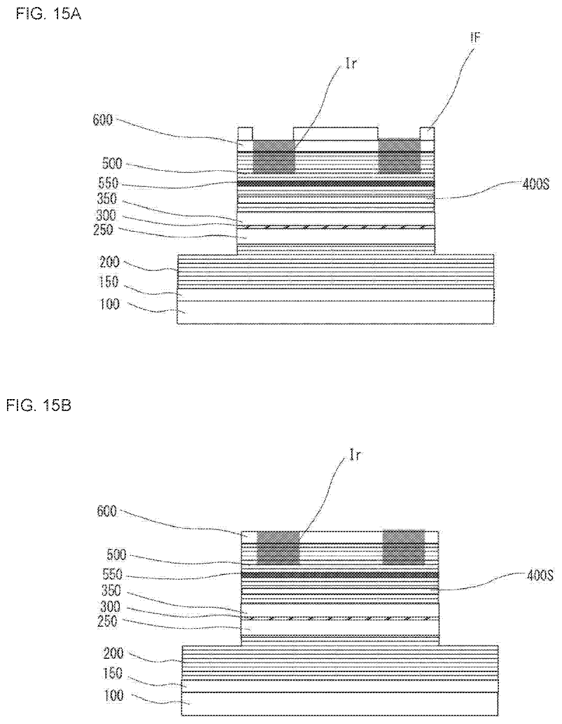

Next, using the insulating film IF as a mask, impurities such as Zn are implanted and diffused through the contact layer 600 by a method such as gas phase or solid phase diffusion (see FIG. 15A). Here, as an example, an impurity diffusion depth is adjusted such that the high-concentration impurity region Ir is located slightly above the impurity diffusion suppression layer 550.

Finally, the insulating film IF is removed by etching (see FIG. 15B).

In the next step S14, the oxidation confinement layer 400 is formed (see FIG. 7B). Specifically, the mesa is exposed to a water vapor atmosphere, and the selected oxide layer 400S is oxidized (selectively oxidized) from a side surface to form the oxidation confinement layer 400 in which the non-oxidized region 400a is surrounded by the oxidized region 400b.

In the next step S15, the anode electrode 700 is formed (see FIG. 8A). Specifically, an electrode material of the anode electrode 700 is formed on the high-concentration impurity region Ir by, for example, sputtering, a vapor deposition method, or the like, and a resist and the electrode material on the resist are lifted off to form the anode electrode 700 on the high-concentration impurity region Ir.

In the next step S16, the insulating film 650 is formed.

Specifically, first, the insulating film 650 made of SiN, for example, is formed on the entire surface (see FIG. 8B).

Next, the insulating film 650 on the anode electrode 700 and on the inner diameter side of the anode electrode 700 is removed by etching (see FIG. 9A). As a result, the anode electrode 700 is exposed, and the emission port 700a is opened.

In the next step S17, the wiring layer 800 is formed (see FIG. 9B). Specifically, the wiring layer 800 is formed on the insulating film 650 such that a part thereof is in contact with the anode electrode 700.

In the next step S18, the cathode electrode 900 is formed (see FIG. 10).

Specifically, first, the entire thickness is set to about 100 μm by polishing a back surface of the substrate 100 (back surface of the wafer).

Next, an electrode material of the cathode electrode 900 is formed into a solid film on the back surface of the substrate 100.

Thereafter, processing such as annealing is performed, thereby the plurality of surface emitting laser arrays in which the plurality of surface emitting lasers 10 is two-dimensionally arranged is formed on one wafer. Thereafter, dicing is performed to separate the plurality of surface emitting laser array chips.

### <<Effects of Surface Emitting Laser and Method for Manufacturing Surface Emitting Laser>>

The surface emitting laser 10 according to the first embodiment includes the first structure ST1 including the first multilayer film reflector 200, the second structure ST2 including the second multilayer film reflector 500, and the active layer 300 disposed between the first and second structures ST1 and ST2. The second structure ST2 has the high-concentration impurity region Ir having a relatively high impurity concentration in at least a part in the thickness direction including the first surface S1 between the first surface S1, which is a surface on a side opposite to the active layer 300 side, and the second surface S2 which is a surface on the active layer 300 side, and has at least one (for example, one) impurity diffusion suppression layer 550 between the first surface S1 and the second surface S2.

In this case, when the current is caused to flow in from the first surface S1 side, the resistance of the second structure ST2 is reduced in the high-concentration impurity region Ir, so that low-voltage driving can be performed. Moreover, the impurity diffusion suppression layer 550 suppresses impurities from flowing out from the high-concentration impurity region Ir to the active layer 300.

As a result, it is possible to provide the surface emitting laser capable of reducing the resistance while suppressing a decrease in reliability according to the surface emitting laser 10 of the first embodiment. Note that, if impurities flow into the active layer 300, a defect due to an excess dopant and a free carrier are generated, which leads to the decrease in reliability.

On the other hand, in a conventional surface emitting laser (see, for example, Patent Document 1), no measure for suppressing diffusion of impurities is taken, and thus, impurities flow out from the high-concentration impurity region Ir to the active layer 300, which leads to the decrease in reliability.

The impurity diffusion suppression layer 550 is preferably disposed between the high-concentration impurity region Ir and the active layer 300. Therefore, it is possible to reliably suppress the outflow of impurities from the high-concentration impurity region Ir to the active layer 300.

The impurity diffusion suppression layer 550 may contain In. Therefore, the impurity diffusion suppression layer 550 can exert an impurity diffusion suppression function.

In a case where the impurity diffusion suppression layer 550 contains In, the In composition is preferably 5% or more. Therefore, the impurity diffusion suppression layer 550 can sufficiently exert the impurity diffusion suppression function.

The impurity diffusion suppression layer 550 may be made of a GaInP-based compound semiconductor or a GaInAs-based compound semiconductor. Therefore, the impurity diffusion suppression layer 550 can exert the impurity diffusion suppression function while performing lattice matching in, for example, an AlGaAs-based surface emitting laser.

The impurity diffusion suppression layer 550 may contain Al. Therefore, the impurity diffusion suppression layer 550 can exert an impurity diffusion suppression function.

In a case where the impurity diffusion suppression layer 550 contains Al, an Al composition is preferably 1% or more and 15% or less. Therefore, the impurity diffusion suppression layer 550 can sufficiently exert the impurity diffusion suppression function.

When an oscillation wavelength of the surface emitting laser 10 is λ, an optical thickness of the impurity diffusion suppression layer 550 is preferably λ/4 or more and λ or less. Therefore, it is possible to suppress the diffusion of excessive impurities to the active layer 300 side due to pile-up of impurities in the impurity diffusion suppression layer 550.

The high-concentration impurity region Ir is annular in plan view, and the difference between the outer diameter and the inner diameter of the high-concentration impurity region Ir is preferably 1 μm or more. Therefore, a sufficient area of the high-concentration impurity region Ir can be secured within a range not affecting laser oscillation.

The second structure ST2 has the oxidation confinement layer 400 between the first surface S1 and the second surface S2. Therefore, a current and light confinement function can be imparted to the surface emitting laser 10.

The impurity diffusion suppression layer 550 is disposed between the first surface S1 and the oxidation confinement layer 400. Therefore, impurities are suppressed from flowing out from the high-concentration impurity region Ir to the selected oxide layer 400S, for example, before the formation of the oxidation confinement layer 400. As a result, an oxidation rate is stabilized when the oxidation confinement layer 400 is formed, the oxidation confinement layer 400 can be formed with good controllability, so that a yield can be improved.

The impurity diffusion suppression layer 550 is disposed between the high-concentration impurity region Ir and the oxidation confinement layer 400. Therefore, it is possible to more reliably suppress the outflow of impurities from the high-concentration impurity region Ir to the oxidation confinement layer 400.

The high-concentration impurity region preferably contains any of Zn, B, and Be. Therefore, the reduction in resistance can be secured.

The surface emitting laser 10 further includes the anode electrode 700 in contact with the high-concentration impurity region Ir. Therefore, contact resistance (contact resistance) between the anode electrode 700 and the contact layer 600 can be reduced.

According to the surface emitting laser array in which the surface emitting lasers 10 are two-dimensionally arranged, the resistance of each of the surface emitting lasers 10 is reduced, and thus, it is possible to provide the surface emitting laser array with lower power consumption.

The method for manufacturing the surface emitting laser 10 according to the first embodiment of the present technology includes: a process of laminating the first structure ST1 including the first multilayer film reflector 200, the active layer 300, and the second structure ST2 including the impurity diffusion suppression layer 550 and the second multilayer film reflector 500 in this order; and a process of diffusing impurities from a surface of the second structure ST2 on a side opposite to the active layer 300 side.

In this case, when impurities are diffused into the second structure ST2, the impurity diffusion suppression layer 550 prevents the impurities from flowing out from the high-concentration impurity region Ir to the active layer 300.

As a result, it is possible to manufacture a surface emitting laser capable of reducing resistance while suppressing a decrease in reliability according to the method for manufacturing the surface emitting laser 10 of the first embodiment.

### 3. SURFACE EMITTING LASER ACCORDING TO MODIFICATION EXAMPLE OF FIRST EMBODIMENT OF PRESENT TECHNOLOGY

### <<Configuration of Surface Emitting Laser>>

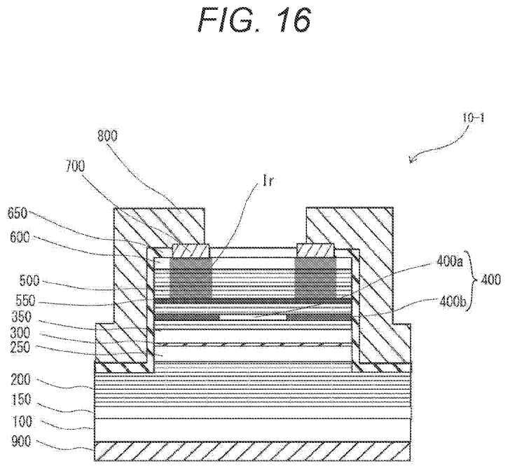

FIG. 16 is a cross-sectional view illustrating a configuration of a surface emitting laser 10-1 according to a modification example of the first embodiment of the present technology. Hereinafter, a case where a surface emitting laser array in which a plurality of the surface emitting lasers 10-1 is two-dimensionally arranged is configured will be described as an example. One surface emitting laser 10-1 of the surface emitting laser array is extracted and illustrated in FIG. 16.

As illustrated in FIG. 16, the surface emitting laser 10-1 has a configuration similar to that of the surface emitting laser 10 according to the first embodiment except that the impurity diffusion suppression layer 550 is provided between a part (upper portion) of the high-concentration impurity region Ir and the oxidation confinement layer 400.

More specifically, a lower end (diffusion depth) of the high-concentration impurity region Ir reaches the impurity diffusion suppression layer 550.

### <<Operation of Surface Emitting Laser and Manufacturing Method Therefor>>

The surface emitting laser 10-1 performs an operation similar to that of the surface emitting laser 10 according to the first embodiment and is manufactured by the similar manufacturing method.

### <<Effects of Surface Emitting Laser>>

According to the surface emitting laser 10-1, effects similar to those of the surface emitting laser 10 according to the first embodiment are achieved, and a diffusion depth of the high-concentration impurity region Ir is deep, and thus, resistance can be further reduced.

### 4. Surface Emitting Laser According to Second Embodiment of Present Technology

### <<Configuration of Surface Emitting Laser>>

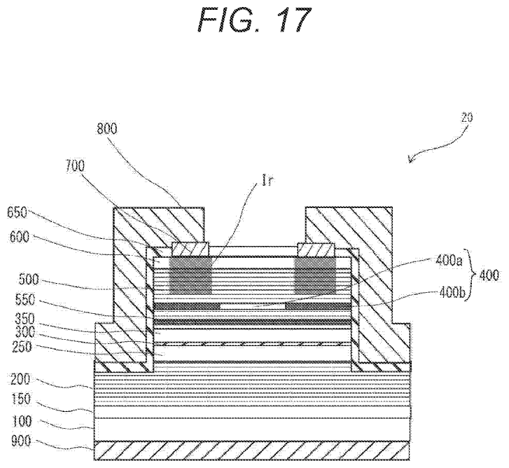

FIG. 17 is a cross-sectional view illustrating a configuration of a surface emitting laser 20 according to a second embodiment of the present technology. Hereinafter, a case where a surface emitting laser array in which a plurality of the surface emitting lasers 20 is two-dimensionally arranged is configured will be described as an example. One surface emitting laser 20 of the surface emitting laser array is extracted and illustrated in FIG. 17.

As illustrated in FIG. 17, the surface emitting laser 20 has a configuration similar to that of the surface emitting laser 10 according to the first embodiment except that the impurity diffusion suppression layer 550 is disposed between the oxidation confinement layer 400 and the active layer 300.

In the surface emitting laser 20, a lower end (diffusion depth) of the high-concentration impurity region Ir is located at a position slightly above the oxidation confinement layer 400.

### <<Operation of Surface Emitting Laser>>

The surface emitting laser 20 performs an operation similar to that of the surface emitting laser 10 according to the first embodiment.

### <<Method for Manufacturing Surface Emitting Laser>>

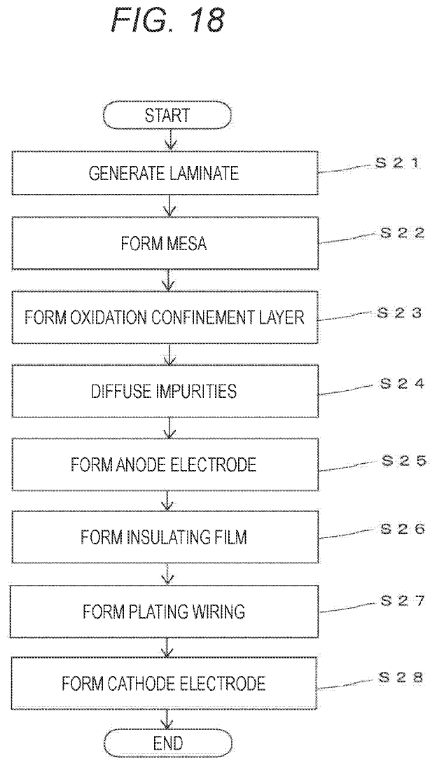

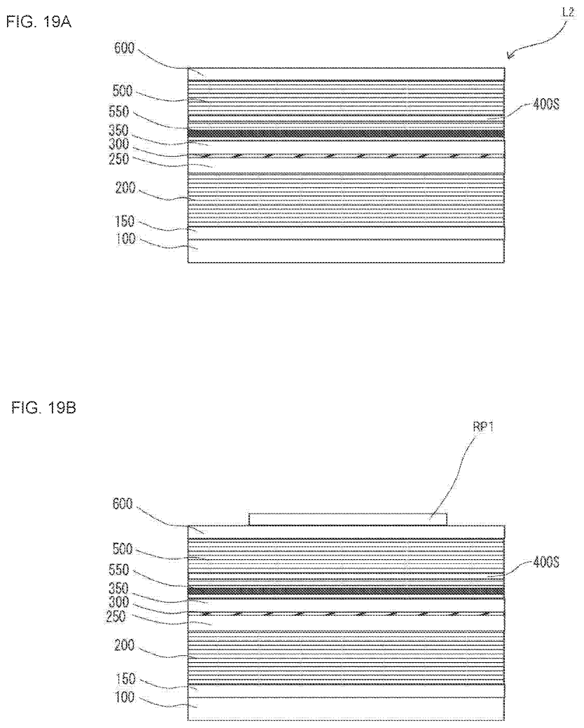

Hereinafter, a method for manufacturing the surface emitting laser 20 according to the second embodiment will be described with reference to FIGS. 18 to 26. FIG. 18 is a flowchart for describing the method for manufacturing the surface emitting laser 20. FIGS. 19A to 26 are cross-sectional views (process cross-sectional views) for each process of the method for manufacturing the surface emitting laser 20. Here, as an example, a plurality of surface emitting laser arrays is simultaneously generated on one wafer, which is a base material of the substrate 100, by a semiconductor manufacturing method (at this time, the plurality of surface emitting lasers 20 of each of the surface emitting laser arrays is also simultaneously generated). Next, the plurality of surface emitting laser arrays integrated in series is separated from each other to obtain a plurality of chip-shaped surface emitting laser arrays (surface emitting laser array chips).

In the first step 521, a laminate L2 is generated. Specifically, using a chemical vapor deposition (CVD) method, for example, a metal organic chemical vapor deposition (MOCVD) method, the buffer layer 150, the first multilayer film reflector 200, the first cladding layer 250, the active layer 300, the second cladding layer 350, the second multilayer film reflector 500 including the impurity diffusion suppression layer 550 and the selected oxide layer 400S in this order from the substrate 100 side, and the contact layer 600 are laminated in this order on the substrate 100 to generate the laminate L2 (see FIG. 19A).

In the next step S22, a mesa is generated.

Specifically, first, the resist pattern RP1 for forming a mesa to be a mesa structure is formed on the laminate L2 (see FIG. 19B).

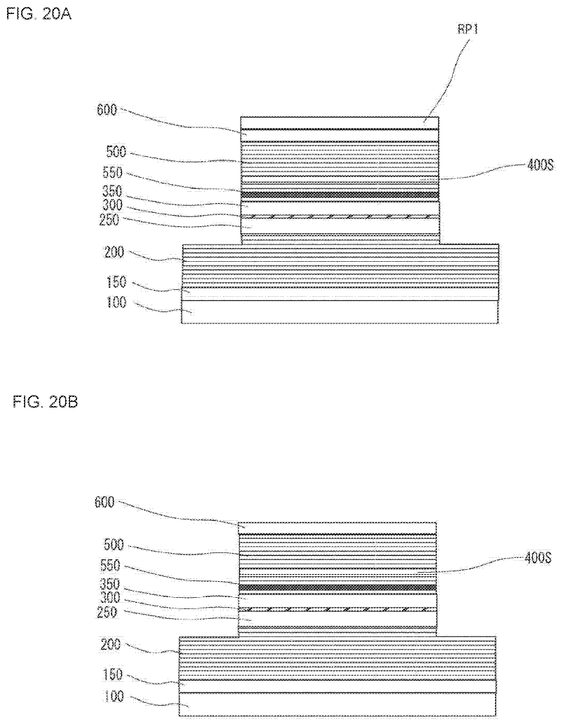

Next, the laminate L2 is etched using the resist pattern RP1 as a mask to form the mesa (see FIG. 20A). The etching here is performed such that an etching bottom surface is located in the first multilayer film reflector 200.

Finally, the resist pattern RP1 is removed by etching (see FIG. 20B).

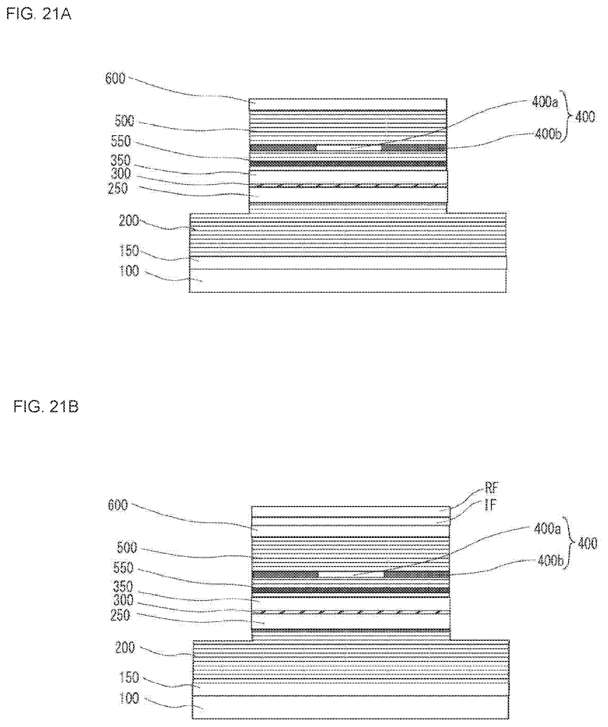

In the next step S23, the oxidation confinement layer 400 is formed (see FIG. 21A). Specifically, the mesa is exposed to a water vapor atmosphere, and the selected oxide layer 400S is oxidized (selectively oxidized) from a side surface to form the oxidation confinement layer 400 in which the non-oxidized region 400a is surrounded by the oxidized region 400b.

In the next step S24, impurities are diffused.

Specifically, first, the insulating film IF made of, for example, SiN and a resist film RF are laminated in this order on an upper surface of the mesa (for example, an upper surface of the contact layer 600) (see FIG. 21B).

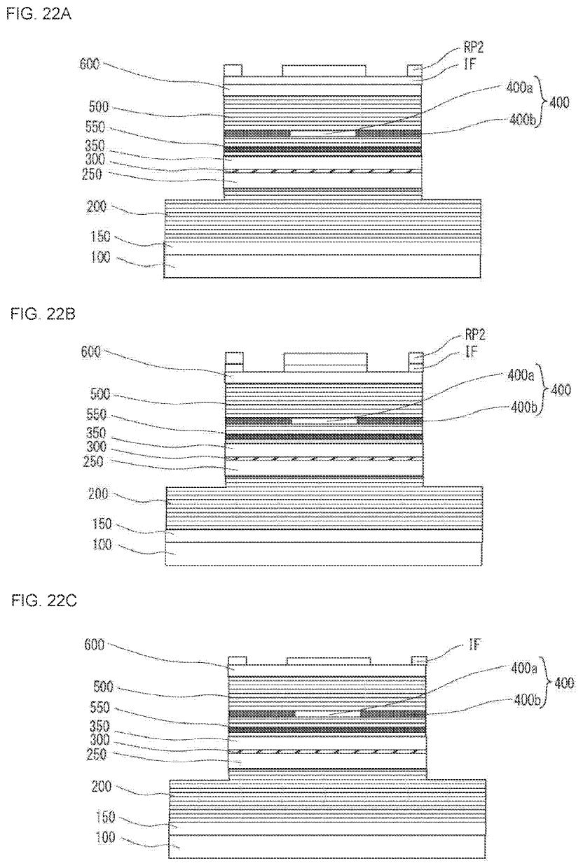

Next, the resist film RF is exposed to form the annular resist pattern RP2 in which a region corresponding to a region where the high-concentration impurity region Ir is to be formed is opened (see FIG. 22A). An opening width (a difference between inner and outer diameters) of the resist pattern RP2 at this time is preferably 1 μm or more.

Next, the insulating film IF is etched using the resist pattern RP2 as a mask (see FIG. 22B).

Next, the resist pattern RP2 is removed by etching (see FIG. 22C).

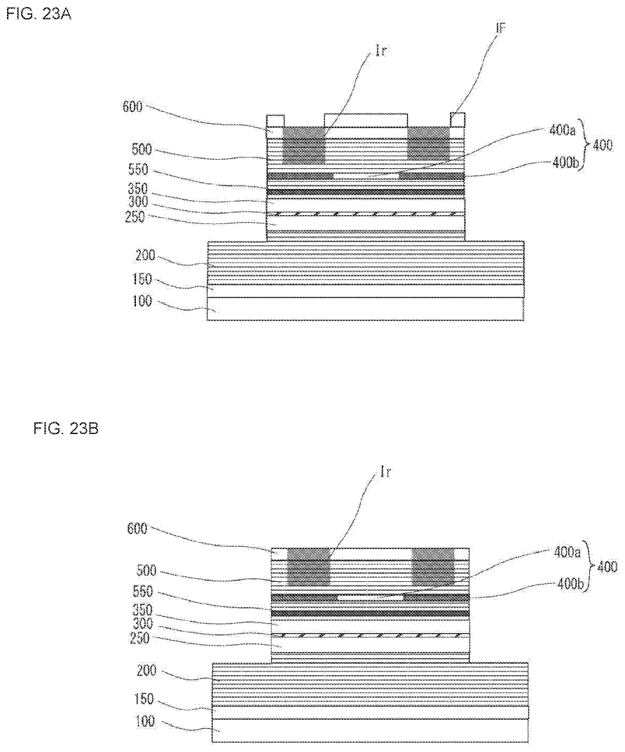

Next, using the insulating film IF as a mask, impurities such as Zn are implanted and diffused through the contact layer 600 by a method such as gas phase or solid phase diffusion (see FIG. 23A). Here, as an example, an impurity diffusion depth is adjusted such that the high-concentration impurity region Ir is located slightly above the impurity diffusion suppression layer 550.

Finally, the insulating film IF is removed by etching (see FIG. 23B).

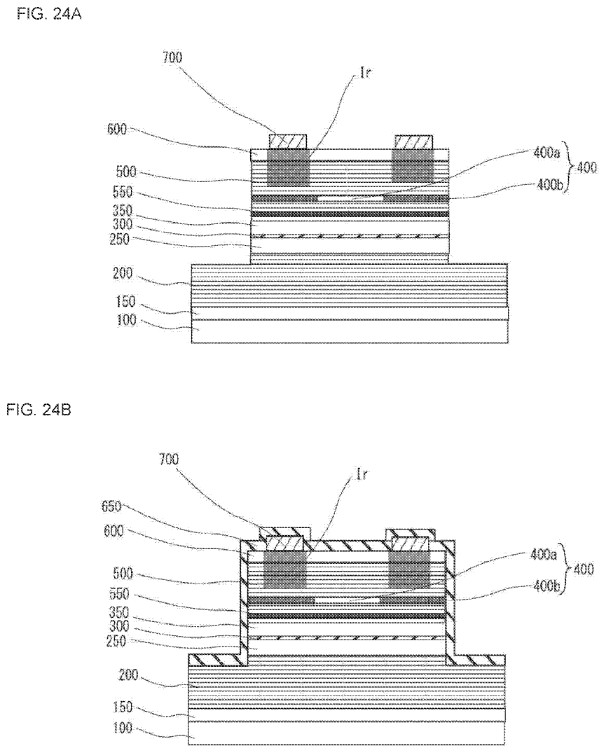

In the next step S25, the anode electrode 700 is formed (see FIG. 24A). Specifically, an electrode material of the anode electrode 700 is formed on the high-concentration impurity region Ir by, for example, sputtering, a vapor deposition method, or the like, and a resist and the electrode material on the resist are lifted off to form the anode electrode 700 on the high-concentration impurity region Ir.

In the next step S26, the insulating film 650 is formed.

Specifically, first, the insulating film 650 made of SiN, for example, is formed on the entire surface (see FIG. 24B).

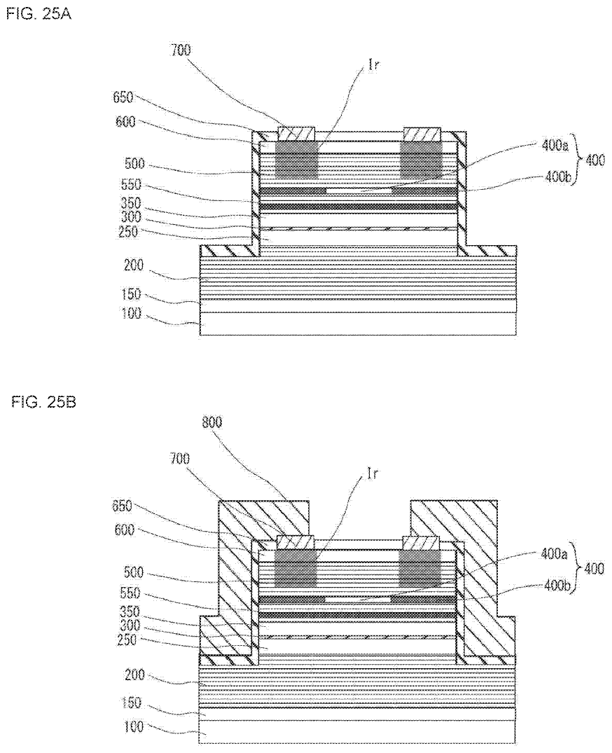

Next, the insulating film 650 on the anode electrode 700 and on the inner diameter side of the anode electrode 700 is removed by etching (see FIG. 25A). As a result, the anode electrode 700 is exposed, and an emission port is opened.

In the next step S27, the wiring layer 800 is formed (see FIG. 25B). Specifically, the wiring layer 800 is formed on the insulating film 650 such that a part thereof is in contact with the anode electrode 700.

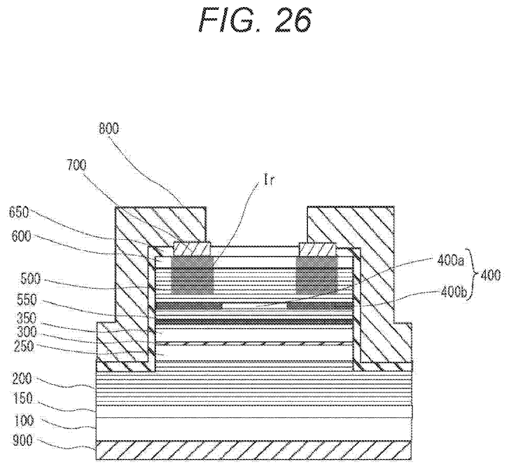

In the next step S28, the cathode electrode 900 is formed (see FIG. 26).

Specifically, first, the entire thickness is set to about 100 μm by polishing a back surface of the substrate 100 (back surface of the wafer).

Next, an electrode material of the cathode electrode 900 is formed into a solid film on the back surface of the substrate 100.

Thereafter, processing such as annealing is performed, thereby the plurality of surface emitting laser arrays in which the plurality of surface emitting lasers 20 is two-dimensionally arranged is formed on one wafer. Thereafter, dicing is performed to separate the plurality of surface emitting laser array chips.

### <<Effects of Surface Emitting Laser>>

According to the surface emitting laser 20, an effect similar to that of the surface emitting laser 10 of the first embodiment is achieved. Note that the surface emitting laser 20 diffuses impurities after the oxidation confinement layer 400 is formed at the time of manufacturing, and thus, the formation of the oxidation confinement layer 400 is not affected.

### 5. Surface Emitting Laser According to Modification Example 1 of Second Embodiment of Present Technology

### <<Configuration of Surface Emitting Laser>>

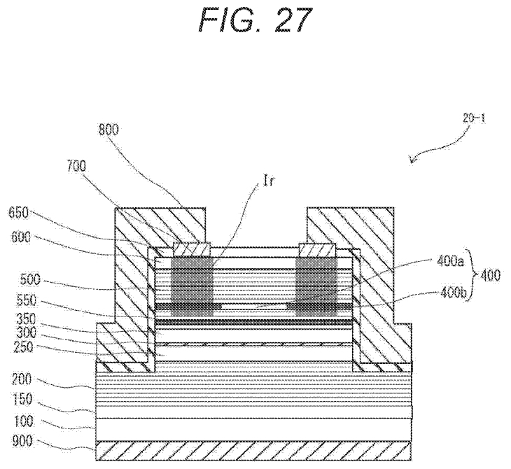

FIG. 27 is a cross-sectional view illustrating a configuration of a surface emitting laser 20-1 according to Modification Example 1 of the second embodiment of the present technology. Hereinafter, a case where a surface emitting laser array in which a plurality of the surface emitting lasers 20-1 is two-dimensionally arranged is configured will be described as an example. One surface emitting laser 20-1 of the surface emitting laser array is extracted and illustrated in FIG. 27.

As illustrated in FIG. 27, the surface emitting laser 20-1 has a configuration similar to that of the surface emitting laser 20 according to the second embodiment except that a lower end (diffusion depth) of the high-concentration impurity region Ir is located between the oxidation confinement layer 400 and the impurity diffusion suppression layer 550.

### <<Operation of Surface Emitting Laser and Manufacturing Method Therefor>>

The surface emitting laser 20-1 performs an operation substantially similar to that of the surface emitting laser 10 according to the first embodiment and is manufactured by a substantially similar manufacturing method.

### <<Effects of Surface Emitting Laser>>

According to the surface emitting laser 20-1, effects similar to those of the surface emitting laser 20 according to the second embodiment are achieved, and a diffusion depth of the high-concentration impurity region Ir is deeper, and thus, resistance can be further reduced.

### 6. SURFACE EMITTING LASER ACCORDING TO MODIFICATION EXAMPLE 2 OF SECOND EMBODIMENT OF PRESENT TECHNOLOGY

### <<Configuration of Surface Emitting Laser>>

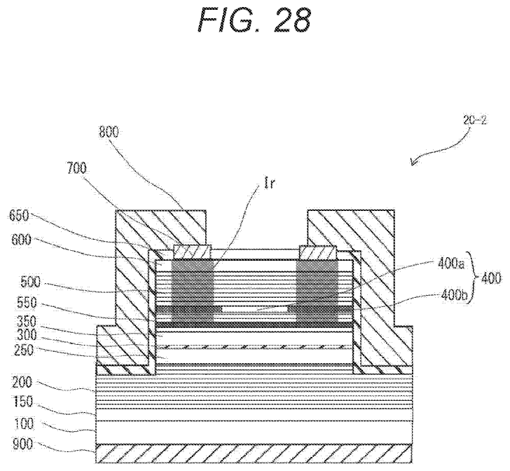

FIG. 28 is a cross-sectional view illustrating a configuration of a surface emitting laser 20-2 according to Modification Example 2 of the second embodiment of the present technology. Hereinafter, a case where a surface emitting laser array in which a plurality of the surface emitting lasers 20-2 is two-dimensionally arranged is configured will be described as an example. One surface emitting laser 20-2 of the surface emitting laser array is extracted and illustrated in FIG. 28.

As illustrated in FIG. 28, the surface emitting laser 20-2 has a configuration similar to that of the surface emitting laser 20 according to the second embodiment except that a lower end (diffusion depth) of the high-concentration impurity region Ir reaches the impurity diffusion suppression layer 550.

### <<Operation of Surface Emitting Laser and Manufacturing Method Therefor>>

The surface emitting laser 20-2 performs an operation substantially similar to that of the surface emitting laser 10 according to the first embodiment and is manufactured by a substantially similar manufacturing method.

### <<Effects of Surface Emitting Laser>>

According to the surface emitting laser 20-2, effects similar to those of the surface emitting laser 20 according to the second embodiment are achieved, and a diffusion depth of the high-concentration impurity region Ir is even deeper, and thus, resistance can be further reduced.

### 7. SURFACE EMITTING LASER ACCORDING TO THIRD EMBODIMENT OF PRESENT TECHNOLOGY

### <<Configuration of Surface Emitting Laser>>

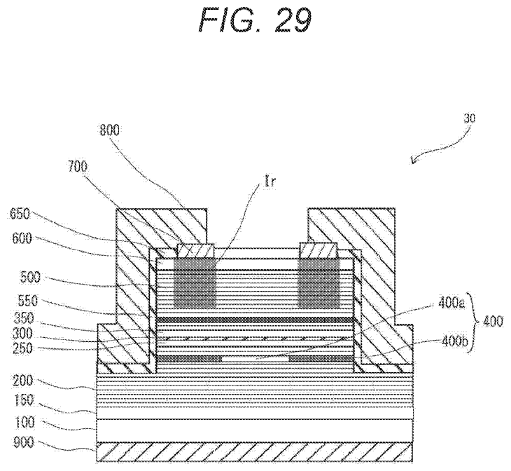

FIG. 29 is a cross-sectional view illustrating a configuration of a surface emitting laser 30 according to a third embodiment of the present technology. Hereinafter, a case where a surface emitting laser array in which a plurality of the surface emitting lasers 30 is two-dimensionally arranged is configured will be described as an example. One surface emitting laser 30 of the surface emitting laser array is extracted and illustrated in FIG. 29.

As illustrated in FIG. 29, the surface emitting laser 30 has a configuration similar to that of the surface emitting laser 10 according to the first embodiment except that the oxidation confinement layer 400 is provided in the first multilayer film reflector 200.

More specifically, in the surface emitting laser 30, the oxidation confinement layer 400 is provided on the first multilayer film reflector 200 (near a bottom of a mesa).

### <<Operation of Surface Emitting Laser and Manufacturing Method Therefor>>

The surface emitting laser 30 performs an operation substantially similar to that of the surface emitting laser 10 according to the first embodiment and is manufactured by a substantially similar manufacturing method.

### <<Effects of Surface Emitting Laser>>

According to the surface emitting laser 30, an effect substantially similar to that of the surface emitting laser 10 of the first embodiment is achieved.

### 8. SURFACE EMITTING LASER ACCORDING TO MODIFICATION EXAMPLE 1 OF THIRD EMBODIMENT OF PRESENT TECHNOLOGY

### <<Configuration of Surface Emitting Laser>>

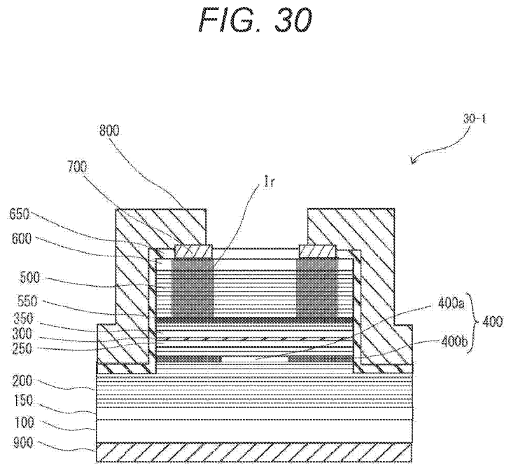

FIG. 30 is a cross-sectional view illustrating a configuration of a surface emitting laser 30-1 according to Modification Example 1 of the third embodiment of the present technology. Hereinafter, a case where a surface emitting laser array in which a plurality of the surface emitting lasers 30-1 is two-dimensionally arranged is configured will be described as an example. One surface emitting laser 30-1 of the surface emitting laser array is extracted and illustrated in FIG. 30.

As illustrated in FIG. 30, the surface emitting laser 30-1 has a configuration similar to that of the surface emitting laser 30 according to the third embodiment except that a lower end (diffusion depth) of the high-concentration impurity region Ir reaches the impurity diffusion suppression layer 550.

### <<Operation of Surface Emitting Laser and Manufacturing Method Therefor>>

The surface emitting laser 30-1 performs an operation substantially similar to that of the surface emitting laser 10 according to the first embodiment and is manufactured by a substantially similar manufacturing method.

### <<Effects of Surface Emitting Laser>>

According to the surface emitting laser 30-1, effects similar to those of the surface emitting laser 30 according to the third embodiment are achieved, and a diffusion depth of the high-concentration impurity region Ir is deeper, and thus, resistance can be further reduced.

### 9. SURFACE EMITTING LASER ACCORDING TO FOURTH EMBODIMENT OF PRESENT TECHNOLOGY

### <<Configuration of Surface Emitting Laser>>

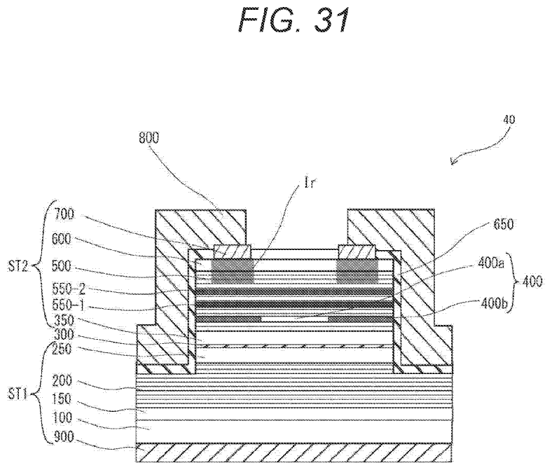

FIG. 31 is a cross-sectional view illustrating a configuration of a surface emitting laser 40 according to a fourth embodiment of the present technology. Hereinafter, a case where a surface emitting laser array in which a plurality of the surface emitting lasers 40 is two-dimensionally arranged is configured will be described as an example. One surface emitting laser 40 of the surface emitting laser array is extracted and illustrated in FIG. 31.

As illustrated in FIG. 31, the surface emitting laser 40 has a configuration similar to that of the surface emitting laser 10 according to the first embodiment except that a plurality of (for example, two) impurity diffusion suppression layers 550 (for example, impurity diffusion suppression layers 550-1 and 550-2) is disposed between a first surface, which is a surface on a side opposite to the active layer 300 side of the second structure ST2, and the oxidation confinement layer 400. Here, the impurity diffusion suppression layer 550-2 is disposed above the impurity diffusion suppression layer 550-1.

More specifically, the plurality of impurity diffusion suppression layers 550 is disposed between at least a part (for example, whole) of the high-concentration impurity region Ir and the oxidation confinement layer 400.

### <<Operation of Surface Emitting Laser and Manufacturing Method Therefor>>

The surface emitting laser 40 performs an operation substantially similar to that of the surface emitting laser 10 according to the first embodiment and is manufactured by a substantially similar manufacturing method.

### <<Effects of Surface Emitting Laser>>

According to the surface emitting laser 40, effects similar to those of the surface emitting laser 10 according to the first embodiment are achieved, and the plurality of impurity diffusion suppression layers 550 is provided, and thus, it is possible to more reliably suppress a decrease in reliability and a decrease in a yield.

### 10. SURFACE EMITTING LASER ACCORDING TO MODIFICATION EXAMPLE 1 OF FOURTH EMBODIMENT OF PRESENT TECHNOLOGY

### <<Configuration of Surface Emitting Laser>>

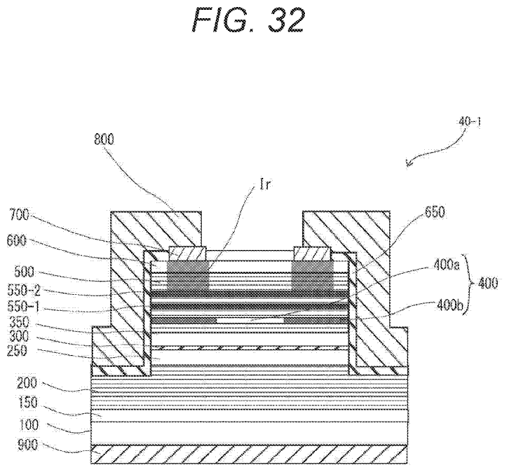

FIG. 32 is a cross-sectional view illustrating a configuration of a surface emitting laser 40-1 according to Modification Example 1 of the fourth embodiment of the present technology. Hereinafter, a case where a surface emitting laser array in which a plurality of the surface emitting lasers 40-1 is two-dimensionally arranged is configured will be described as an example. One surface emitting laser 40-1 of the surface emitting laser array is extracted and illustrated in FIG. 32.

The surface emitting laser 40-1 has a configuration similar to that of the surface emitting laser 40 according to the fourth embodiment except that a lower end (diffusion depth) of the high-concentration impurity region Ir reaches the impurity diffusion suppression layer 550-2.

### <<Operation of Surface Emitting Laser and Manufacturing Method Therefor>>

The surface emitting laser 40-1 performs an operation substantially similar to that of the surface emitting laser 10 according to the first embodiment and is manufactured by a substantially similar manufacturing method.

### <<Effects of Surface Emitting Laser>>

According to the surface emitting laser 40-1, effects similar to those of the surface emitting laser 40 according to the fourth embodiment are achieved, and a diffusion depth of the high-concentration impurity region Ir is deeper, and thus, resistance can be further reduced.

### 11. SURFACE EMITTING LASER ACCORDING TO MODIFICATION EXAMPLE 2 OF FOURTH EMBODIMENT OF PRESENT TECHNOLOGY

### <<Configuration of Surface Emitting Laser>>

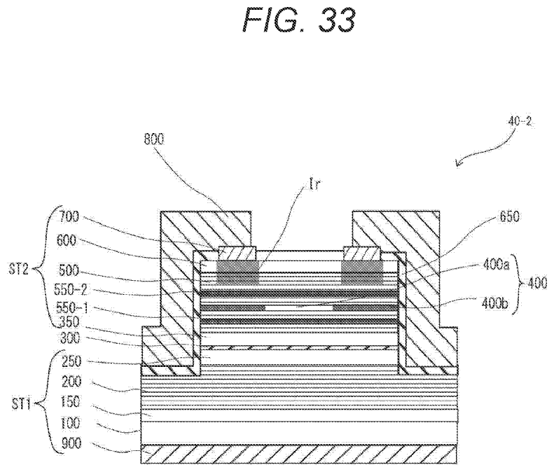

FIG. 33 is a cross-sectional view illustrating a configuration of a surface emitting laser 40-2 according to Modification Example 2 of the fourth embodiment of the present technology. Hereinafter, a case where a surface emitting laser array in which a plurality of the surface emitting lasers 40-2 is two-dimensionally arranged is configured will be described as an example. One surface emitting laser 40-2 of the surface emitting laser array is extracted and illustrated in FIG. 33.

As illustrated in FIG. 33, the surface emitting laser 40-2 has a configuration similar to that of the surface emitting laser 40 according to the fourth embodiment except that a part (for example, the impurity diffusion suppression layer 550-2) of the plurality of (for example, two) impurity diffusion suppression layers 550 is disposed between a first surface, which is a surface on a side opposite to the active layer 300 side of the second structure ST2 and the oxidation confinement layer 400, and the other part (for example, the impurity diffusion suppression layer 550-1) of the plurality of (for example, two) impurity diffusion suppression layers 550 is disposed between the oxidation confinement layer 400 and the active layer 300.

More specifically, a part (for example, the impurity diffusion suppression layer 550-2) of the plurality of impurity diffusion suppression layers 550 is disposed between at least a part (for example, whole) of the high-concentration impurity region Ir and the oxidation confinement layer 400, and the other part (for example, the impurity diffusion suppression layer 550-1) of the plurality of impurity diffusion suppression layers is disposed between the oxidation confinement layer 400 and the active layer 300.

### <<Operation of Surface Emitting Laser and Manufacturing Method Therefor>>

The surface emitting laser 40-2 performs an operation substantially similar to that of the surface emitting laser 10 according to the first embodiment and is manufactured by a substantially similar manufacturing method.

### <<Effects of Surface Emitting Laser>>

According to the surface emitting laser 40-2, an effect substantially similar to that of the surface emitting laser 40 of the fourth embodiment is achieved.

### 12. MODIFICATION EXAMPLE OF PRESENT TECHNOLOGY

The present technology is not limited to each of the above-described embodiments and modification examples, and various modifications can be made.

Although the surface emitting type surface emitting laser that emits light to the front surface side (upper surface side) of the substrate 100 has been described as an example in each of the above-described embodiments and modification examples, the surface emitting laser according to the present technology can also be applied to a back surface emitting type surface emitting laser that emits light to the back surface side (lower surface side) of the substrate 100.

Although the AlGaAs-based surface emitting laser has been described in each of the above-described embodiments and modification examples, the surface emitting laser according to the present technology is also applicable to other material-based surface emitting lasers.

In each of the above-described embodiments and modifications, both the first and second multilayer film reflectors 200 and 500 are semiconductor multilayer film reflectors, but the present technology is not limited thereto. For example, at least one of the first or second multilayer film reflector 200 or 500 may be a dielectric multilayer film reflector.

In the surface emitting laser according to each of the above-described embodiments and modification examples, the oxidation confinement layer 400 is not necessarily provided.

In the surface emitting laser according to each of the above-described embodiments and modification examples, the buffer layer 150 is not necessarily provided.

In the surface emitting laser according to the present technology, the contact layer 600 is not necessarily provided.

Although the surface emitting laser array in which the surface emitting lasers 10 are two-dimensionally arranged has been described as an example in each of the above-described embodiments and modification examples, the present technology is not limited thereto. The present technology is also applicable to a surface emitting laser array in which the surface emitting lasers 10 are one-dimensionally arranged, the single surface emitting laser 10, and the like.

In the surface emitting laser according to each of the above embodiments and modification examples, the conductivity types (p-type and n-type) may be interchanged.

Each of the above-described embodiments and modification examples can be combined within a range not contradictory to each other.

In each of the above-described embodiments and modification examples, the described specific numerical values, shapes, materials (including compositions), and the like are merely examples, and are not limited thereto.

### 13. APPLICATION EXAMPLE TO ELECTRONIC DEVICE

The technology according to the present disclosure (the present technology) can be applied to various products (electronic devices). For example, the technology according to the present disclosure may be implemented as an element mounted on any type of mobile body such as an automobile, an electric vehicle, a hybrid electric vehicle, a motorcycle, a bicycle, a personal mobility, an airplane, a drone, a ship, a robot, and the like.

The surface emitting laser according to the present technology can also be applied as, for example, a light source of a device that forms or displays an image by laser light (for example, a laser printer, a laser copier, a projector, a head-mounted display, a head-up display, or the like).

### 14. EXAMPLE IN WHICH SURFACE EMITTING LASER IS APPLIED TO DISTANCE MEASURING DEVICE

Hereinafter, application examples of the surface emitting laser according to each of the above-described embodiments, examples, and modification examples will be described.

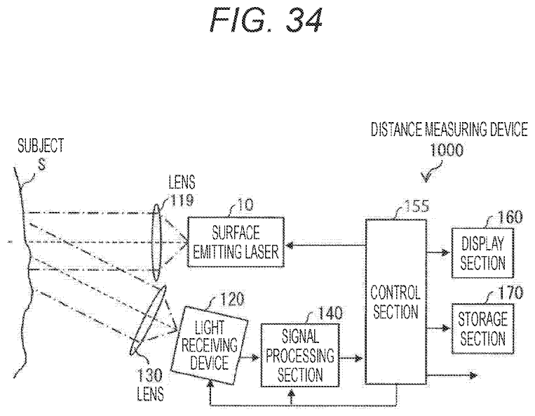

FIG. 34 illustrates an example of a schematic configuration of a distance measuring device 1000 including the surface emitting laser 10 as an example of an electronic device according to the present technology. The distance measuring device 1000 measures the distance to a subject S by a time of flight (TOF) method. The distance measuring device 1000 includes the surface emitting laser 10 as a light source. The distance measuring device 1000 includes, for example, the surface emitting laser 10, a light receiving device 120, lenses 119 and 130, a signal processing section 140, a control section 155, a display section 160, and a storage section 170.

The light receiving device 120 detects light reflected by the subject S. The lens 119 is a lens for collimating the light emitted from the surface emitting laser 10-1, and is a collimating lens. The lens 130 is a lens for condensing light reflected by the subject S and guiding the light to the light receiving device 120, and is a condenser lens.

The signal processing section 140 is a circuit for generating a signal corresponding to a difference between a signal input from the light receiving device 120 and a reference signal input from the control section 155. The control section 155 includes, for example, a time to digital converter (TDC). The reference signal may be a signal input from the control section 155, or may be an output signal of a detecting section that directly detects the output of the surface emitting laser 10. The control section 155 is, for example, a processor that controls the surface emitting laser 10, the light receiving device 120, the signal processing section 140, the display section 160, and the storage section 170. The control section 155 is a circuit that measures a distance to the subject S on the basis of a signal generated by the signal processing section 140. The control section 155 generates a video signal for displaying information regarding the distance to the subject S, and outputs the video signal to the display section 160. The display section 160 displays the information regarding the distance to the subject S on the basis of the video signal input from the control section 155. The control section 155 stores information regarding the distance to the subject S in the storage section 170.

In the present application example, instead of the surface emitting laser 10, any one of the above surface emitting lasers 10-1, 20, 20-1, 20-2, 30, 30-1, 40, 40-1, and 40-2 can be applied to the distance measuring device 1000.

### 15. EXAMPLE IN WHICH DISTANCE MEASURING DEVICE IS MOUNTED ON MOBILE BODY

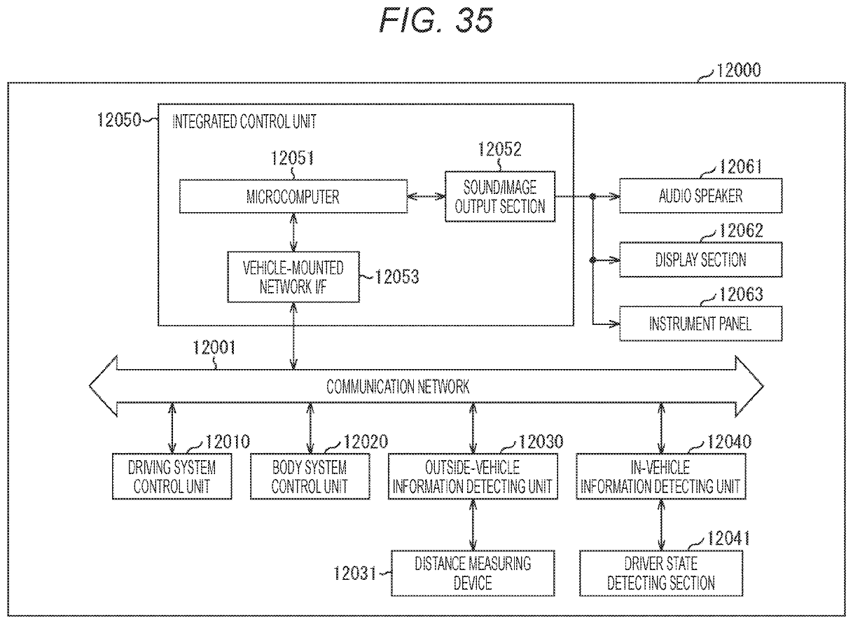

FIG. 35 is a block diagram illustrating a schematic configuration example of a vehicle control system as an example of a mobile body control system to which the technology according to the present disclosure can be applied.

A vehicle control system 12000 includes a plurality of electronic control units connected to each other via a communication network 12001. In the example illustrated in FIG. 35, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as the functional configuration of the integrated control unit 12050.

The driving system control unit 12010 controls operations of devices related to a driving system of the vehicle in accordance with various kinds of programs. For example, the driving system control unit 12010 functions as a control device of a driving force generation device for generating a driving force of the vehicle such as an internal combustion engine or a driving motor, a driving force transmission mechanism for transmitting the driving force to wheels, a steering mechanism for adjusting a steering angle of the vehicle, a braking device for generating a braking force of the vehicle, and the like.

The body system control unit 12020 controls operations of various devices mounted on the vehicle body according to various programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives input of these radio waves or signals, and controls a door lock device, a power window device, a lamp, and the like of the vehicle.

The outside-vehicle information detecting unit 12030 detects information outside the vehicle on which the vehicle control system 12000 is mounted. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (subject S) outside the vehicle, and acquires distance data obtained by the measurement. The outside-vehicle information detecting unit 12030 may perform object detection processing of a person, a car, an obstacle, a sign, or the like on the basis of the acquired distance data.

The in-vehicle information detecting unit 12040 detects information inside the vehicle. The in-vehicle information detecting unit 12040 is, for example, connected with a driver state detecting section 12041 that detects the state of a driver. The driver state detecting section 12041 includes, for example, a camera that captures an image of the driver, and the in-vehicle information detecting unit 12040 may calculate the degree of fatigue or the degree of concentration of the driver or may determine whether or not the driver is dozing off on the basis of the detection information input from the driver state detecting section 12041.

The microcomputer 12051 can calculate a control target value of the driving force generator, the steering mechanism, or the braking device on the basis of the information regarding the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to realize functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

Furthermore, the microcomputer 12051 controls the driving force generation device, the steering mechanism, the braking device, or the like on the basis of the information around the vehicle acquired by the outside-vehicle information detecting unit 12030 or the in-vehicle information detecting unit 12040, thereby performing cooperative control for the purpose of automated driving or the like in which the vehicle autonomously travels without depending on the operation of the driver.

Furthermore, the microcomputer 12051 can output a control command to the body system control unit 12020 on the basis of the information regarding the outside of the vehicle acquired by the outside-vehicle information detecting unit 12030. For example, the microcomputer 12051 can perform cooperative control for the purpose of preventing glare, such as switching from a high beam to a low beam, by controlling the head lamp according to the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example of FIG. 35, an audio speaker 12061, a display section 12062, and an instrument panel 12063 are depicted as the output device. The display section 12062 may, for example, include at least one of an on-board display or a head-up display.

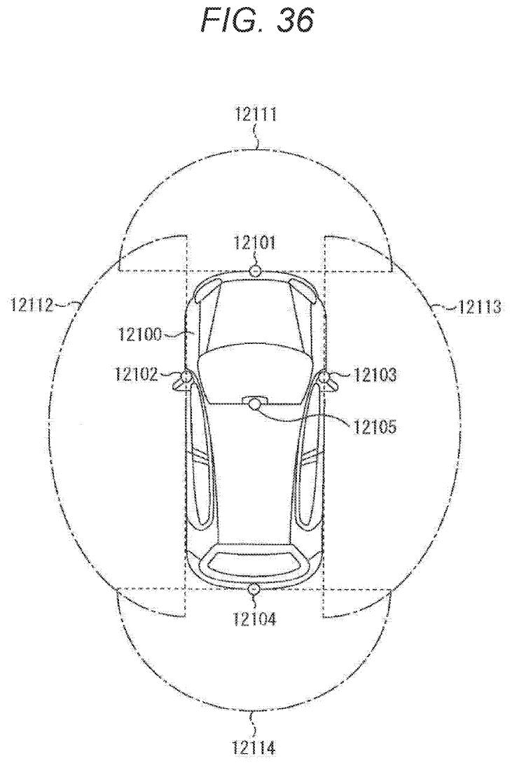

FIG. 36 is a view illustrating an example of an installation position of the distance measuring device 12031.

In FIG. 36, a vehicle 12100 includes distance measuring devices 12101, 12102, 12103, 12104, and 12105 as the distance measuring device 12031.

The distance measuring devices 12101, 12102, 12103, 12104, and 12105 are provided, for example, at positions such as a front nose, side mirrors, a rear bumper, a back door, and an upper portion of a windshield in a vehicle interior of the vehicle 12100. The distance measuring device 12101 provided on the front nose and the distance measuring device 12105 provided on the upper portion of the windshield in the vehicle cabin mainly acquire data of the front side of the vehicle 12100. The distance measuring devices 12102 and 12103 provided at the sideview mirrors mainly acquire data on the sides of the vehicle 12100. The distance measuring device 12104 provided on the rear bumper or the back door mainly acquires data behind the vehicle 12100. The data in front of the vehicle acquired by the distance measuring devices 12101 and 12105 is mainly used for detecting a preceding vehicle, a pedestrian, an obstacle, a traffic light, a traffic sign, or the like.

Note that FIG. 36 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided on the rear bumper or the back door.

For example, the microcomputer 12051 obtains a distance to each three-dimensional object in the detection ranges 12111 to 12114 and a temporal change of the distance (relative speed with respect to the vehicle 12100) on the basis of the distance data obtained from the distance measuring devices 12101 to 12104, thereby extracting, as a preceding vehicle, a three-dimensional object traveling at a predetermined speed (for example, 0 km/h or more) in substantially the same direction as the vehicle 12100, in particular, the closest three-dimensional object on a traveling path of the vehicle 12100. Moreover, the microcomputer 12051 can set a following distance to be maintained in front of a preceding vehicle in advance, and perform automated brake control (including following stop control), automated acceleration control (including following start control), or the like. It is thus possible to perform cooperative control intended for automated driving that makes the vehicle travel automatedly without depending on the operation of the driver or the like.

For example, on the basis of the distance data obtained from the distance measuring devices 12101 to 12104, the microcomputer 12051 can classify three-dimensional object data regarding three-dimensional objects into two-wheeled vehicles, ordinary vehicles, large vehicles, pedestrians, and other three-dimensional objects such as utility poles, extract the three-dimensional object data, and use the three-dimensional object data for automatic avoidance of obstacles. For example, the microcomputer 12051 identifies obstacles in the periphery of the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

An example of a mobile body control system to which the technology according to the present disclosure can be applied has been described above. The technology according to the present disclosure can be applied to the distance measuring device 12031 among the configurations described above.

Furthermore, the present technology can also have the following configurations.

(1) A surface emitting laser including:

a first structure including a first multilayer film reflector;

a second structure including a second multilayer film reflector; and

an active layer disposed between the first and second structures,

in which the second structure includes a high-concentration impurity region having a relatively high impurity concentration in at least a part in a thickness direction including a first surface between the first surface, which is a surface on a side opposite to a side of the active layer, and a second surface which is a surface on the side of the active layer, and includes at least one impurity diffusion suppression layer between the first surface and the second surface.

(2) The surface emitting laser according to (1), in which

the second multilayer film reflector has a pair of a high Al composition layer having a relatively high Al composition, and a low Al composition layer having a relatively low Al composition, and

an optical thickness of the high Al composition layer is thicker than an optical thickness of the low Al composition layer.

(3) The surface emitting laser according to (1) or (2), in which the impurity diffusion suppression layer is disposed between at least a part of the high-concentration impurity region and the active layer.

(4) The surface emitting laser according to any one of (1) to (3), in which the impurity diffusion suppression layer contains In.

(5) The surface emitting laser according to any one of (1) to (4), in which the impurity diffusion suppression layer is made of a GaInP-based compound semiconductor or a GaInAs-based compound semiconductor.

(6) The surface emitting laser according to any one of (1) to (4), in which the impurity diffusion suppression layer contains Al.

(7) The surface emitting laser according to (6), in which the impurity diffusion suppression layer has an Al composition of 1% or more and 15% or less.

(8) The surface emitting laser according to any one of (1) to (7), in which when an oscillation wavelength of the surface emitting laser is λ, an optical thickness of the impurity diffusion suppression layer is λ/4 or more and λ or less.

(9) The surface emitting laser according to any one of (1) to (8), in which the high-concentration impurity region has an annular shape in plan view, and a difference between an outer diameter and an inner diameter of the high-concentration impurity region is 1 μm or more.

(10) The surface emitting laser according to any one of (1) to (9), in which the at least one impurity diffusion suppression layer is a plurality of impurity diffusion suppression layers.

(11) The surface emitting laser according to any one of (1) to (10), in which the second structure has an oxidation confinement layer between the first surface and the second surface.

(12) The surface emitting laser according to (11), in which the impurity diffusion suppression layer is disposed between the first surface and the oxidation confinement layer.

(13) The surface emitting laser according to (11) or (12), in which the impurity diffusion suppression layer is disposed between at least a part of the high-concentration impurity region and the oxidation confinement layer.

(14) The surface emitting laser according to any one of (11) to (13), in which the impurity diffusion suppression layer is disposed between the oxidation confinement layer and the active layer.

(15) The surface emitting laser according to any one of (11) to (14), in which the at least one impurity diffusion suppression layer is a plurality of impurity diffusion suppression layers, and at least one of the plurality of impurity diffusion suppression layers is disposed between the first surface and the oxidation confinement layer.

(16) The surface emitting laser according to any one of (11) to (15), in which the at least one impurity diffusion suppression layer is a plurality of impurity diffusion suppression layers, and at least one of the plurality of impurity diffusion suppression layers is disposed between at least a part of the high-concentration impurity region and the oxidation confinement layer.

(17) The surface emitting laser according to any one of (11) to (16), in which

the at least one impurity diffusion suppression layer is a plurality of impurity diffusion suppression layers, and

at least one of the plurality of impurity diffusion suppression layers is disposed between the oxidation confinement layer and the active layer.

(18) The surface emitting laser according to any one of (1) to (17), in which the high-concentration impurity region contains any of Zn, B, and Be.

(19) The surface emitting laser according to any one of (11) to (18), in which the at least one impurity diffusion suppression layer is a plurality of impurity diffusion suppression layers, a part of the plurality of impurity diffusion suppression layers is disposed between the first surface and the oxidation confinement layer, and another part of the plurality of impurity diffusion suppression layers is disposed between the oxidation confinement layer and the active layer.

(20) The surface emitting laser according to any one of (11) to (19), in which the at least one impurity diffusion suppression layer is a plurality of impurity diffusion suppression layers, a part of the plurality of impurity diffusion suppression layers is disposed between at least a part of the high-concentration impurity region and the oxidation confinement layer, and another part of the plurality of impurity diffusion suppression layers is disposed between the oxidation confinement layer and the active layer.

(21) The surface emitting laser according to any one of (1) to (20), in which the first structure has an oxidation confinement layer in the first multilayer film reflector.

(22) The surface emitting laser according to any one of (1) to (21), in which the first and second structures and the active layer are made of an AlGaAs-based compound semiconductor or an AlGaInP-based compound semiconductor.

(23) The surface emitting laser according to any one of (1) to (22), in which the first and second structures and the active layer are made of a GaN-based compound semiconductor.

(24) A surface emitting laser array in which a plurality of the surface emitting lasers according to any one of (1) to (23) is arranged.

(25) An electronic device including the surface emitting laser according to any one of (1) to (23).

(26) An electronic device including the surface emitting laser array according to (24).

(27) The present technology also provides a method for manufacturing a surface emitting laser, the method including:

a process of laminating a first structure including a first multilayer film reflector, an active layer, and a second structure including an impurity diffusion suppression layer and a second multilayer film reflector on a substrate in this order; and

a process of diffusing impurities from a surface of the second structure on a side opposite to a side of the active layer.

(28) The method for manufacturing a surface emitting laser according to (27), in which the second structure includes a selected oxide layer, and the method further includes a process of oxidizing the selected oxide layer from a side surface to form an oxidation confinement layer after the diffusing process.

(29) The method for manufacturing a surface emitting laser according to (27), in which the second structure includes a selected oxide layer, and the method further includes a process of oxidizing the selected oxide layer from a side surface to form an oxidation confinement layer before the diffusing process.

### REFERENCE SIGNS LIST

10, 10-1, 20, 20-1, 30, 30-1, 40, 40-1, 40-2 Surface emitting laser
100 Substrate
200 First multilayer film reflector
300 Active layer
400 Oxidation confinement layer
400S Selected oxide layer
500 Second multilayer film reflector
550, 550-1, 550-2 Impurity diffusion suppression layer
Ir High-concentration impurity region
ST1 First structure
ST2 Second structure
S1 First surface
S2 Second surface

1. A surface emitting laser comprising:
a first structure including a first multilayer film reflector;
a second structure including a second multilayer film reflector; and
an active layer disposed between the first and second structures,
wherein the second structure includes a high-concentration impurity region having a relatively high impurity concentration in at least a part in a thickness direction including a first surface between the first surface, which is a surface on a side opposite to a side of the active layer, and a second surface which is a surface on the side of the active layer, and includes at least one impurity diffusion suppression layer between the first surface and the second surface.

2. The surface emitting laser according to claim 1, wherein
the second multilayer film reflector has a pair of a high Al composition layer having a relatively high Al composition, and a low Al composition layer having a relatively low Al composition, and
an optical thickness of the high Al composition layer is thicker than an optical thickness of the low Al composition layer.

3. The surface emitting laser according to claim 1, wherein the impurity diffusion suppression layer is disposed between at least a part of the high-concentration impurity region and the active layer.

4. The surface emitting laser according to claim 1, wherein the impurity diffusion suppression layer contains In.

5. The surface emitting laser according to claim 1, wherein the impurity diffusion suppression layer is made of a GaInP-based compound semiconductor or a GaInAs-based compound semiconductor.

6. The surface emitting laser according to claim 1, wherein the impurity diffusion suppression layer contains Al.

7. The surface emitting laser according to claim 6, wherein the impurity diffusion suppression layer has an Al composition of 1% or more and 15% or less.

8. The surface emitting laser according to claim 1, wherein
when an oscillation wavelength of the surface emitting laser is λ,
an optical thickness of the impurity diffusion suppression layer is λ/4 or more and λ or less.

9. The surface emitting laser according to claim 1, wherein
the high-concentration impurity region has an annular shape in plan view, and
a difference between an outer diameter and an inner diameter of the high-concentration impurity region is 1 μm or more.

10. The surface emitting laser according to claim 1, wherein the at least one impurity diffusion suppression layer is a plurality of impurity diffusion suppression layers.

11. The surface emitting laser according to claim 1, wherein the second structure has an oxidation confinement layer between the first surface and the second surface.

12. The surface emitting laser according to claim 11, wherein the impurity diffusion suppression layer is disposed between the first surface and the oxidation confinement layer.

13. The surface emitting laser according to claim 11, wherein the impurity diffusion suppression layer is disposed between at least a part of the high-concentration impurity region and the oxidation confinement layer.

14. The surface emitting laser according to claim 11, wherein the impurity diffusion suppression layer is disposed between the oxidation confinement layer and the active layer.

15. The surface emitting laser according to claim 11, wherein
the at least one impurity diffusion suppression layer is a plurality of impurity diffusion suppression layers, and
at least one of the plurality of impurity diffusion suppression layers is disposed between the first surface and the oxidation confinement layer.

16. The surface emitting laser according to claim 11, wherein
the at least one impurity diffusion suppression layer is a plurality of impurity diffusion suppression layers, and
at least one of the plurality of impurity diffusion suppression layers is disposed between at least a part of the high-concentration impurity region and the oxidation confinement layer.

17. The surface emitting laser according to claim 11, wherein
the at least one impurity diffusion suppression layer is a plurality of impurity diffusion suppression layers, and
at least one of the plurality of impurity diffusion suppression layers is disposed between the oxidation confinement layer and the active layer.

18. The surface emitting laser according to claim 1, wherein the high-concentration impurity region contains any of Zn, B, and Be.

19. The surface emitting laser according to claim 11, wherein
the at least one impurity diffusion suppression layer is a plurality of impurity diffusion suppression layers,
a part of the plurality of impurity diffusion suppression layers is disposed between the first surface and the oxidation confinement layer, and
another part of the plurality of impurity diffusion suppression layers is disposed between the oxidation confinement layer and the active layer.

20. The surface emitting laser according to claim 11, wherein
the at least one impurity diffusion suppression layer is a plurality of impurity diffusion suppression layers,
a part of the plurality of impurity diffusion suppression layers is disposed between at least a part of the high-concentration impurity region and the oxidation confinement layer, and
another part of the plurality of impurity diffusion suppression layers is disposed between the oxidation confinement layer and the active layer.
